(19) United States
(12) Patent Application Publication
(10) Pub. No.: US 2024/0120822 A1
(43) Pub. Date: Apr. 11, 2024

(54) CIRCUIT FOR A MEDICAL DEVICE OR FOR ANOTHER DEVICE, MEDICAL DEVICE AND METHOD

(71) Applicant: Neuro Device Group S .A., Warsaw (PL)

(72) Inventors: Pawel PROKOPCZYK, Warsaw (PL); Kizysztof Mateusz MALEJ, Warsaw (PL); Mariusz GIERGIELEWICZ, Warsaw (PL); Adam JANKIEWICZ, Warsaw (PL)

(21) Appl. No.: 18/276,192

(22) PCT Filed: Feb. 10, 2022
(86) PCT No.: PCT/EP2022/053283

§ 371 Date: Aug. 7, 2023

(30) Foreign Application Priority Data
Feb. 19, 2021 (EP) 21461518.9

(51) Int. Cl. H02M 1/00; H02M 1/08; H03F 3/30

(52) U.S. Cl. CPC H02M 1/0006; H02M 1/0012; H02M 1/0025; H02M 1/08; H03F 3/303

(57) ABSTRACT

Disclosed is a circuit (100) for a medical device, comprising: —a voltage converter (110, 300) which is configured to provide at least one supply potential (HV) depending on a control signal (302, PWM) provided to the voltage converter (110, 300), —a control unit (P) which is configured to provide the control signal (302, PWM) for the voltage converter (110, 300), —a signal source (TCA, 400) which is powered by the at least one supply potential (+HV) and which is configured to provide an output signal at an output of the signal source (TCA, 400), wherein the signal source (TCA, 400) is configured to provide the output signal dependent on an input signal (120) at an input of the signal source (TCA, 400), —wherein the control unit (P) comprises: —a prediction unit (160) which is configured to predict a change in the characteristic of the output signal based on at least one of a) at least one value of the input signal and b) at least one detected value of the output signal, and —an adjusting unit (160) which is configured to adjust the control signal (302, PWM) based on the predicted change in the characteristic of the output signal.

The disclosure relates to an electronic circuit for a medical device or for another device, to a brain stimulation device, to a corresponding method and to corresponding computer related items.

There are several types of medical electronic devices, especially wearable devices, on the market which are powered by a battery or by an accumulator, e.g. by a rechargeable battery.

One type of a medical device is a brain stimulation device, which enables therapeutic applications and non-therapeutic applications. An example of a therapeutic application is the treatment of aphasia or of motoric abilities by stimulating specific regions of the brain. An example of a non-therapeutic application is the training of a sportsman in order to improve his or her reaction abilities, their cognitive abilities and/or their recognition abilities. An example for the amount of current which may be applied to a person is 2 mA (milliampere) delivered for instance with 20 Volts. These exemplary values result in a power of 40 mW (milliwatt). However, these values may change, e.g. due to changes of impedance between stimulation electrodes. For this reason power supply may need to be capable of delivering higher amount of voltage to ensure proper stimulation in varying conditions. Further electrical power may be needed for a power converter and/or for the operation of a signal generating circuit in addition to the delivered output current. These electronic components may generate high power loss if they are powered with higher amount of voltage.

However, efficiency of power supply is not only an issue for medical devices but also for all electronic devices which are powered by a battery/accumulator, for instance wearable consumer devices, telecommunication devices, electric cars etc.

Wearable devices enable a high user comfort because of the unlimited freedom to move together with the device.

More generally, efficiency of power supply is also an issue for devices which are driven by the power grid of electricity providers. Such devices are typically plugged into a power source and restrict therefor the movement of the device and/or of a user of the device.

It is an object of the invention to provide a highly power efficient electrical device, preferably a medical device. Preferably, the device should allow a long usage of a battery/accumulator.

Further, a corresponding medical device, a corresponding method and corresponding computer related items should be provided.

This object is solved by the circuit according to claim 1. Further embodiments are given in the dependent claims. Furthermore, the object is solved by the subject matter of the independent claims.

### SUMMARY OF THE INVENTION

Circuit for a medical device or for another device, comprising:
a voltage converter which is configured to provide at least one supply potential depending on a control signal provided to the voltage converter,
a control unit which is configured to provide the control signal for the voltage converter,
a signal source which is powered by the at least one supply potential and which is configured to provide an output signal at an output of the signal source, wherein the signal source is configured to provide the output signal dependent on an input signal at an input of the signal source,
an optional detection unit which is configured to detect at least one signal value of the output signal,
wherein the control unit comprises:
   a prediction unit which is configured to predict a change in a characteristic of the output signal based on at least one of the following: a) at least one value of the input signal and b) at least one detected value of the output signal, and
   an adjusting unit which is configured to adjust the control signal based on the predicted change in the characteristic of the output signal.

Method, preferably using a circuit according to one of the preceding claims, comprising:
providing a voltage converter which generates a supply voltage dependent on a control signal,
providing a signal source which is powered by the supply voltage, wherein the signal source generates an output signal dependent on an input signal,
predicting a change of a characteristic of the output signal, and
adjusting the control signal dependent on the predicted change.

A circuit for a medical device may comprise:
a voltage converter which is configured to provide at least one supply potential depending on a control signal provided to the voltage converter, and/or
a control unit which is configured to provide the control signal for the voltage converter, and/or
a signal source which is powered by the at least one supply potential and which is configured to provide an output signal at an output of the signal source.

The signal source may be configured to provide the output signal dependent on or based on an input signal at an input of the signal source.

The control unit may comprise:
a prediction unit which is configured to predict a change in a characteristic of the output signal, and
an adjusting unit which is configured to adjust the control signal based on the predicted change in the characteristic of the output signal.

The circuit may be used also in non-medical devices. The circuit may be configured to adaptively adjust a supply potential depending on an output signal of the signal source. This may result in an operation method which guarantees that the supply potential is always high enough to fulfill the demand but not higher or not essentially higher than necessary. If compared for instance with a device which has a fixed or constant supply potential or supply voltage, it is evident that the proposed device needs less electrical power which results in longer battery life time.

If the circuit is comprised in a medical device, especially in a device for a stimulation of the brain, the function of the device may be important for the life of a person and/or for the health of a person. Thus, power efficiency is also an important issue.

The predicted characteristic change of the output signal may be a predicted voltage amplitude change, for instance a momentary voltage plus a predicted change of the momentary voltage. The change in output voltage may be generally a result of a change in the load impedance, as the output voltage may be current independent on the load (e.g. trans-conductance amplifier) and as the output voltage is a multiplication product of the output current and of the impedance of the load. In another example, the change in output voltage may be a result of a change in the programmed output current. Furthermore, there may be more than one of the mentioned reasons for a change of the output value simultaneously. Thus, such a voltage amplitude change may occur due to changes of a current stimulation signal or due to impedance changes during stimulation with a defined current signal, even with a constant current signal. Especially, brain stimulators and most of the tissue stimulators may be in general current stimulators which use a constant stimulation current.

At least one offset voltage and/or at least one scaling factor, e.g. K_LA or K_P as mentioned below may be considered for adjusting the control signal in order to have enough margin for the power supply if the predicted change or the predicted value does deviate from the actual change of the characteristic or of the value which is relevant in the future. Some changes in output voltage may be predicted due to the nature of the load being an organic tissue while some unexpected changes may also happen. Thus the combination of a prediction unit and/or proportional margin and/or of a reaction unit may have advantageous technical effects with regard to reducing overall power consumption.

The circuit may be an electronic circuit which may comprise several discrete electronic components arranged for instance on a printed circuit board. At least one integrated circuit may be used in addition to the discrete elements. Alternatively, no integrated circuit may be used.

In an alternative embodiment the circuit may be realized mainly or completely in integrated technology, for instance in CMOS (Complementary Metal Oxide Semiconductor) technology or in another semiconductor technology.

The control signal may be a digital control signal, for instance a PWM (Pulse Width Modulation) signal which is easy to generate. The control signal may be generated by a processor or by a digital control unit. The control unit may comprise a processor which executes instructions of a program. Alternatively, a control unit without a processor may be used, for instance a finite state machine.

The prediction unit may be configured to predict the change of the output signal based on a characteristic of an electrical signal, for instance based on the input signal of the signal source or on the output signal of the signal source. Alternatively or additionally, other sources may be used to predict the change, for instance an empirical model and/or a theoretical model and/or an implicit model (e.g. using artificial neural networks). A mathematical formula or equation may form the basis of a model.

The device may be a device that is powered by a battery/accumulator, for instance a wearable consumer device, e.g. a telecommunication device, e.g. a smartphone. Alternatively, the device may be an electric car, etc.

According to an embodiment, the prediction unit may be configured to consider a change of an output signal voltage of the output signal, especially of an output signal voltage of the output signal of the signal source. Alternatively, a change of the output signal current of the output signal of the signal source may be used as a basis for prediction in the prediction unit.

However, usage of output signal voltage may be simpler than usage of output signal current, e.g. the resulting circuit may be simpler.

According to a further embodiment, the prediction unit may be configured to consider a look-ahead factor. The look ahead factor may be a factor that comprises an assumption about the future signal value of the output signal, e.g. the output signal voltage or the output signal current. Although, a specific example is given below for usage of a look ahead factor within a special equation, the look ahead factor may be used in other equations as well. Moreover, there are several ways to estimate the look ahead factor. The look ahead factor may realize an extrapolation of the output signal, e.g. in order to predict future values of the output signal.

A first characteristic may relate to a first signal value of the electrical signal at a first time and a second characteristic may relate to a second signal value of the electrical signal at a second time which is after the first time, preferably within the same rising or falling signal part of the electrical signal after the first time. The prediction unit may be configured to predict the change of the output signal based on the first signal value and on the second signal value, preferably based on the difference of the second signal value and of the first signal value. This embodiment may allow to adapt the power supply voltage or potential in real time (e.g. less than 20 ms (milliseconds) or less than 30 ms) or in near real time (e.g. less than 100 ms) to the output signal thereby improving the efficiency of the electronic circuit considerably. The time for adaption may be more than 0.1 ms or more than 1 ms.

According to one elementary example, the prediction unit may be configured to predict a change of the output signal related to or depending on impedance changes, using an extrapolation based on a first time derivative of the measured quantity. This simply assumes the future value will rise in time by the same constant factor equal to the measured change in time in past measurements.

Another example may be a prediction based on a theoretical model of tissue conduction properties, e.g. the impedance of the tissue under current flow tends to get reduced in time due to ions concentration flow in the tissue. Additional phenomena such as drying off of the conducting gel or liquid (if used) during the time of stimulation may also have an impact on the change (rise) in impedance and may be modelled.

Alternatively, a first characteristic may relate to a first signal value of the electrical signal at a first peak (extremum) of the electrical signal at a first time. A second characteristic may relate to a second signal value of the electrical signal at a second peak (extremum) of the electrical signal at a second time. The second time may be a time after the first time, preferably within the next oscillation of the electrical signal after the first time. The prediction unit may be configured to predict the change of the characteristic of the output signal based on the first signal value and on the second signal value. The difference of the second signal value and of the first signal value may be used to predict the change. The peak may be a maximum and/or a minimum of the signal curve. Thus, the embodiment may be used for bipolar signals or for unipolar signals. A peak may be easy to detect digitally or using analog circuit techniques.

The first characteristic may relate to a first peak to peak value (amplitude) of the electrical signal calculated based on a first maximum peak value of the electrical signal at the first time and on a first minimum peak value of the electrical signal. The first maximum peak value may be adjacent to the first minimum peak value, e.g. within the adjacent swing of the electrical signal. The first minimum peak value may occur earlier or later than first maximum peak value.

The second characteristic may relate to a second peak to peak (amplitude) value of the electrical signal calculated based on a second maximum peak value of the electrical signal at the second time and a second minimum peak value of the electrical signal. The second maximum peak value may be adjacent to the second minimum peak value, e.g. within the adjacent swing of the electrical signal. The second minimum peak value may occur earlier or later than second maximum peak value.

The peak to peak amplitude may be a bipolar signal. Alternatively, the peak to peak amplitude may also be determined for a unipolar signal, for instance for a unipolar signal comprising a constant or a slowly changing offset value, preferably slowly changing with regard to a periodic change of the amplitude. “Adjacent” may mean within an immediately previous oscillation or within immediately following oscillation of the electrical signal.

Peak to peak vale detection may enable high accuracy of prediction.

Alternatively, for instance in the case of a symmetrical signal, only positive peak values or only negative peak values may be used for prediction in order to simplify the circuit and/or the method.

The adjusting unit may be configured to adjust the control signal to increase the supply voltage when the predicted change indicates that the output signal or the amplitude of the output signal will increase. Additionally or alternatively, the adjusting unit may be configured to adjust the control signal to decrease the supply voltage when the predicted change indicates that the output signal or the amplitude of the output signal will decrease. Furthermore, the adjusting unit may be configured to maintain the digital control signal as it is when the predicted change indicates that the output voltage or the amplitude of the output signal of the amplifier will not change or will not change significantly. Thus, adjusting is possible according to simple rules which are easy to implement into an electronic circuit.

If negative voltages or negative currents are relevant a decrease or an increase of the absolute value of the supply voltage dependent on a decrease or dependent on an increase of an absolute value of predicted change, e.g. voltage may be used. Exemplary, the absolute value of −10 Volt is 10 Volt, i.e. only the amount of the physical quantity but not the sign has to be considered.

The prediction unit may be configured to predict the change based on an alternating electrical signal comprising a varying amplitude, wherein preferably a frequency of the variation of the amplitude may be lower than a frequency of the alternating signal, e.g. lower than 50 percent of the frequency of the alternating signal or lower than 10 percent of the frequency of the alternating signal. These signals may be especially appropriate for electric brain stimulation devices and/or for medical devices. The alternating electrical signal may have a constant signal period or signal frequency of the basic signal and/or a constant signal period or signal frequency of an envelope signal. The alternating electrical signal may be a bipolar electric signal or a unipolar electric signal.

Alternatively, non-alternating especially non-periodic signals may be used for prediction as is mentioned below in more detail.

Further, the circuit may comprise a detecting unit. The detecting unit may be configured to detect the output voltage of the signal source, e.g. of a trans-conductance amplifier (TCA), of a transmittance amplifier or of another type of amplifier. The prediction unit may be configured to predict the change based on the detected output voltage or based on a characteristic value which is generated based on the measured output voltage. Alternatively or additionally, the detecting unit may be configured to detect the impedance of a load of the amplifier. The prediction unit may be configured to predict the change based on the detected impedance. The usage of the impedance or of the resistance of a load may be especially relevant for loads which are formed by living tissue, e.g. of living persons. The load may vary because of internal biological processes within the person. Other sources of load variations may be formed by the attachment of electrodes which may be attached allowing a residual relative movement between the electrode and the skin of a person. Moreover, gels may be used to improve electrical contact between electrode and skin. The physical characteristic of the gel may vary over time, for instance due to lower humidity within the gel. This may result in a change of the impedance of the load. If it is possible to consider load variations, it may be possible to achieve that specific output signals may be generated within very small tolerance regions, e.g. for voltage and/or for current and/or for timing.

A special case of detecting may be measuring, e.g. using SI (System International) units or units of another standardized system. As already mentioned, a special case of an impedance is the resistance, e.g. the Ohmic resistance.

The prediction unit may be configured to predict the change based on a characteristic value of the detected output signal voltage or based on a change in the output signal voltage and based on a calculated characteristic value of the output voltage, calculated preferably based on the detected impedance and on a known value of the momentary current signal or of the momentary amplitude of an electrical current through the load at the output of the amplifier, preferably using the following formula:

V_{OUT}=MAX(|V_{MEAS}|,|V_{CALC}|) (2)
where:
V_{MEAS} is the measured output signal voltage or the voltage amplitude of the output signal,
V_{CALC} is a calculated output signal voltage or the voltage amplitude of the output signal, e.g. according to formula (4) or to another equation,
∥ is the absolute value function, and
MAX is the maximum function.

V_{CALC}=Z*I_{AMP} (4)
where:
Z is the measured impedance, and
I_{AMP} is the goal current amplitude.

By the voltage amplitude of the output signal it should be understood the difference between expected or measured peak positive and expected or measured peak negative voltage points in a voltage waveform in a given time period in case of a signal changing polarity, such as AC signal or noise signal. Alternatively, the output signal voltage may refer to only peak values within the positive upper half of a signal or to only the negative peak values within the lower half of a signal, e.g. of a symmetrical signal. In case of a signal not changing polarity, such as DC, the output signal voltage may be understood as peak value of voltage within the given time point in the direction equal to the signal polarity, i.e. an absolute value of the peak.

In both cases, the output signal voltage is not necessarily the maximum amplitude voltage the TCA can physically generate, rather a signal waveform shape parameter.

A maximum-operator operation may be used. The maximum may be determined easy by a simple comparison. Both values which are considered to determine the maximum may vary, e.g. strongly. A prediction which is based on two values or on more than two values may improve the accuracy of the prediction, e.g. the prediction is always on the save side, i.e. the power supply of the signal source or of the amplifier may be high enough to provide the needed power but not too high in order to save energy of a battery or other power supply on the input side of the power/voltage converter.

The prediction unit may be configured to consider a change of an output signal voltage, preferably of a detected output signal voltage (amplitude or peak to peak value) and/or of a calculated output signal voltage, at the output of the signal source, preferably according to the following formula:

$${V}_{LA} = MAX ( \vert {k}_{LA} * \frac{{dV}_{OUT}}{dt} \vert , 0 ) \qquad ( 3 )$$

where:
dV_{OUT} is the change in the output signal voltage or the change in the voltage amplitude of the output signal during a considered time period dt,
dt is the considered time period or time frame,
k_{LA} is the look-ahead factor, and
MAX is the maximum function.

This formula (3) is easy to implement into a digital control unit, especially in a digital prediction unit. In the given formula (3) only the positive derivative (rise in time) is taken into consideration for safety from signal deterioration. The look-ahead factor K_LA may be optionally used. The value of the look-ahead factor K_LA may be in the range of 0.5 to 3 or in the range of 1 to 3 to give only two examples. Instead of the value “0” another value may be used for comparison.

The prediction unit may be configured to calculate a supply voltage value according to the following formula:

V_{PROG}=(1+kₚ)*(V_{OUT}+V_{SAT})+V_{LA} (1)
where:
kₚ is an optional percentage margin,
V_{OUT} is the output signal voltage, e.g. the output voltage amplitude and may be calculated according to formula (2),
V_{SAT} is an optional saturation voltage of the TCA or, alternatively, an optional voltage drop on TCA, and
V_{LA} is calculated according to formula (3).

Again, this formula (1) is easily to implement into a digital control unit, especially in a digital prediction unit. The control may be very fast because only simple calculations have to be performed.

Alternatively or additionally, the prediction unit may be configured to consider a heuristic model or a theoretical model of the change of the impedance of a load at an output of the signal source for the prediction of the value, preferably a heuristic model or a theoretical model of a load which is formed by the tissue of a person. The impedance may depend on the amount of stimulation current in transcutaneous stimulation, or may depend on the frequency of the stimulation signal to give only two examples. The usage of a mathematical equation may be an implementation of a model. Alternatively, artificial neural network (e.g. deep neural network models) approaches or other approaches may be used for the model, e.g. for an implicit model. A special case of the impedance is the Ohmic resistance. The person may be a patient or a person which is coached or trained in order to improve its performance level, preferably using electrical currents and/or electrical voltage which stimulate the brain, especially specific regions within the brain and/or biological neural networks within specific regions of the brain.

The circuit may comprise a current control unit for controlling the current at the output of the signal source according to an electrical signal which corresponds to a reference current. The reference current may be an alternating reference current (AC) having a constant maximal amplitude or an alternating reference current having a varying amplitude. The amplitude may be defined as the maximal deviation from a mean value of an oscillating signal. These, currents may be relevant for brain stimulation, e.g. (tACS, transcranial alternating current stimulation) or for other medical applications or for applications in other technical fields. The current control may be a closed-loop control, see variant 2 mentioned below. Alternatively, an open loop current control may be used, see variant 1 mentioned below.

The current control unit may comprise a control deviation unit which may generate an actuating signal depending on the amount of deviation of a measured electrical signal which has a value corresponding to the current through a load at the output of the signal source and depending on a signal which represents the momentary value of the reference current. Thus, a closed-loop current control unit may be realized in a simple manner.

Voltage signals may be used which represent the reference current and the measured current. This may allow the usage of operational amplifiers which are available for reasonable costs. The current control unit may generate the actuating signal such that the deviation is decreased, e.g. performing a minimization or another kind of optimization.

The circuit may comprise a signal conditioning unit which may be configured to transform two input signals, preferably two input voltage signals, to a single output signal preferably without offset. A single output voltage signal may be used. The single output signal may correspond to a reference current. The single output signal may be used as an input signal of the output trans-conductance amplifier (TCA) or of another signal source.

The signal conditioning unit may comprise a subtraction unit. The subtraction unit may be realized using an operational amplifier. The subtraction unit may calculate the difference of a positive value and (minus) a negative value which results in the double value if both input values are equal. A calibration factor may be available which may be selected for instance to 2 or to another appropriate value. One active DAC output and a constant reference output (e.g. +1.65V) may be used, e.g. resulting in the following mapping of voltages:
0 Volt minus 1.65 Volt is equal to −1.65 Volt,
+1.65 Volt minus 1.65 Volt is equal to 0 Volt, and
3.3 Volt minus 1.65 Volt is equal to +1.65 Volt.

The voltage converter may comprise:
a switching transistor, preferably a MOSFET, and/or
an inductor, preferably one terminal of the conductor connected to or connectable to a power source and the other terminal of the inductor connected to a first circuit node which is connected with a first doped area of the switching transistor, and/or
a first diode, preferably the anode of the first diode connected to the first circuit node and the cathode of the first diode connected to a positive voltage/potential power rail, and/or
a first capacitor, preferably one electrode of the first capacitor connected to the cathode of the first diode.

This is a simple but nevertheless efficient realization of a voltage converter comprising only a low number of electrical components. The embodiment may be appropriate to generate a positive supply potential or a positive voltage (regarding the difference of the positive potential and the ground potential, e.g. 0 Volt).

Additionally or alternatively, the voltage converter may comprise a charge pump to generate a negative operation potential. The charge pump may comprise:
a second capacitor, preferably one electrode of the second capacitor connected to the first circuit node, and/or
a second diode and a third diode.

The anode of the second diode may be connected to the cathode of the third diode forming a second circuit node which is also connected to the other electrode of the second capacitor. A third capacitor may be used. One electrode of the third capacitor may be connected to the anode of the third diode forming a negative voltage/potential power rail.

Thus, the voltage converter may be a bipolar voltage converter, e.g. generating positive potential, negative potential and optionally ground potential, or a unipolar voltage converter, e.g. generating positive potential and ground potential or alternatively generating negative potential and ground potential but no negative potential.

The signal source may comprise a trans-conductance amplifier (TCA), preferably operating according to:

I_{PAT}=gm*(V_{INPUT1}−V_{INPUT2}) (5)
where:
I_{PAT} is the output current of the TCA,
gm is a conductance value, preferably within the range of 0.5 mS to 10 mS or in the range of 0.75 mS to 5 mS,
V_INPUT1 is a first input voltage on a non-inverting input node of the amplifier, and
V_INPUT2 is a second input voltage on an inverting input node of the amplifier.

The trans-conductance amplifier (TCA) may be especially appropriate for medical applications and/or for brain stimulation applications. The TCA accepts one or more voltage inputs and the outputs current may be independent (within certain limits) on the load.

The signal source may comprise:
a bias generating unit, and/or
a first amplifier stage, preferably at least one input of the first amplifier stage connected to at least one output of the bias generating unit, and/or
a second amplifier stage, preferably at least one input of the second amplifier stage connected to at least one output of the first amplifier stage, preferably via at least one current mirror unit.

This amplifier may operate using a bipolar operating voltage. The amplifier is comparably simple and robust. The amplifier circuit may be designed to have a very high output impedance, i.e. very low dependence of output current with load (patient) impedance while voltage is allowed to adjust accordingly. Furthermore, the amplifier circuit may be operated over a wide supply voltage range. Further technical effects are mentioned below.

The signal source may comprise two input nodes which are connected directly with a differential input signal. This variant (variant 1 mentioned below) may be preferred in a circuit which does not use open loop control of current.

Alternatively, the signal source may comprise a first input node and a second input node which are connected to different input signals respectively (variant 2). A non-inverting input node may be connected to a signal which corresponds to a required or desired output current of the signal source. An inverting input node may be connected to an error signal which may indicate the value of the difference between a signal corresponding to a measured current and a signal corresponding to a reference current. The reference current may be equal to the required output current of the signal source.

Especially, for non-periodic input signals and/or output signals, the circuit may be configured such that the input signal is a signal having a constant value or a value which does not change more than 10 percent from a maximum value within a time window. The time window may have a length of at least 1 second or of at least 10 seconds or of at least 30 seconds.

The time window may have a length of less than 10 minutes, less than 5 minutes, less than 4 minutes, less than 3 minutes, less than 2 minutes or less than 1 minute. The circuit may be configured such that changes of the output signal based on variations of an impedance of a load at an output of the signal source may be predicted and/or detected. Thus, the circuit may be used for constant current tissue stimulation of a patient or of a subject, e.g. for constant brain current stimulation.

The circuit may be configured such that a first characteristic relates to a first signal value of the output signal at a first time and a second characteristic relates to a second signal value of the output signal at a second time which is after the first time. Furthermore, the circuit may be configured such that the first signal value and the second signal value are from the same raising or falling signal part of the electrical output signal. The prediction unit may be configured to predict the change of the output signal based on the first signal value and on the second signal value, preferably based on the difference of the second signal value and of the first signal value. Thus, energy may be used efficiently even if a constant input signal is used, e.g. an input signal that corresponds to a constant output current of the signal source/TCA. Variations in the value of the output signal may have their reasons in impedance variations of a load at the output of the signal source/TCA. As mentioned already for other embodiments above, the supply voltage may be adapted closely to the expected output voltage of the signal source/TCA or to another output signal of this signal source.

The invention relates in a second aspect to a medical device, preferably to a brain stimulation device. The medical device or the brain stimulation device may comprise a circuit as described in one of the embodiments mentioned above. The brain stimulation device or the medical device may comprise at least one electrode, e.g. appropriate to make contact to the skin of a human person. The device may comprise a supporting structure, e.g. comprising a closed ring or a ring which can be closed and opened, for arranging the at least one electrode on the head of a person or on another part of the body. The person may be trained non-therapeutically by the device, e.g. by the brain stimulation device, or the person may be a patient which is treated therapeutically by the device, e.g. by the brain stimulation device. The device may be wearable in order to allow the person to move freely while using the device. Thus, the technical effects mentioned above for the circuit may also apply to the device.

A third aspect of the invention relates to a method, preferably using a circuit according to one of the embodiments mentioned above. The method may comprise:
providing a voltage converter which generates a supply voltage dependent on a control signal, and/or
providing a signal source which is powered by the supply voltage.

The signal source may generate an output signal on its output dependent on an input signal on its input. A change of a characteristic of the output signal may be predicted. The control signal may be adjusted dependent on the predicted change. Thus, the technical effects mentioned above for the circuit may also apply to the method.

Further, a non-transitory computer readable medium, a computer program product and a system are provided. The system may comprise:
one control unit or more than one control unit; and/or
a non-transitory computer-readable medium, configured to store computer-readable instructions that, when executed by the one or more control unit, cause the system to perform at least a part of or the method mentioned above.

The computer program product may be stored on a computer readable medium or may be comprised within an analog and/or digital signal which is transmitted via a telecommunication network (wired and/or wireless) and/or an internet protocol (IP) based network, for instance the internet.

Another aspect relates to a circuit for a medical device or for another electronic device, comprising:
a voltage converter which is configured to provide at least one supply potential depending on a control signal provided to the voltage converter,
a control unit which is configured to provide the control signal for the voltage converter,
a signal source which is powered by the at least one supply potential and which is configured to provide an output signal at an output of the signal source,
   wherein the signal source is configured to provide the output signal dependent on an input signal at an input of the signal source,
wherein the control unit comprises:
   a prediction unit which is configured to predict a change of a characteristic of the output signal based on at least one of a) at least one value of the input signal and b) at least one detected value of the output signal, and
   an adjusting unit which is configured to adjust the control signal based on the predicted change in the characteristic of the output signal.

All embodiments mentioned above are also valid for this aspect, especially not only for alternative b) but also for alternative a). Thus, all dependent claims 1 to 21 are also valid for this aspect. The same applies to medical device claim 22, to method claim 23 and to claim 24 directed to several computer related items.

The making and using of the presently preferred embodiments are discussed in detail below. It should be appreciated, however, that the present disclosure provides many applicable concepts that can be embodied in a wide variety of specific contexts. The specific embodiments discussed are merely illustrative of specific ways to make and use the disclosed concepts, and do not limit the scope of the claims.

Moreover, same reference numerals refer to same technical features if not stated otherwise. As far as “may” is used in this application it means the possibility of doing so as well as the actual technical implementation. The present concepts of the present disclosure will be described with respect to preferred embodiments below in a more specific context namely a medical system for brain stimulation. The disclosed concepts may also be applied, however, to other situations and/or arrangements as well, for instance for other medical applications, e.g. ultra-sonic (US) signal generation, preferably for medical imaging. Radio frequency transmitter application or other applications of signal generating sources may be considered as well

The foregoing has outlined rather broadly the features and technical advantages of embodiments of the present disclosure. Additional features and advantages of embodiments of the present disclosure will be described hereinafter. These features may be the subject-matter of dependent claims. It should be appreciated by those skilled in the art that the conception and specific embodiments disclosed may be readily utilized as a basis for modifying or designing other structures or processes for realizing concepts which have the same or similar purposes as the concepts specifically discussed herein. It should also be recognized by those skilled in the art that equivalent constructions do not depart from the spirit and scope of the disclosure, such as defined in the appended claims.

In this document, for instance V_MEAS is the same as V_{MEAS}. The same is true with regard to other names using the underscore character “Y_X” or a lower index Y_{X} where Y and X are placeholders, i.e. Y is equal to V and X is equal to MEAS in the case of V_MEAS or V_{MEAS}).

For a more complete understanding of the presently disclosed concepts and the advantages thereof, reference is now made to the following description in conjunction with the accompanying drawings. The drawings are not drawn to scale. In the drawings the following is shown in:

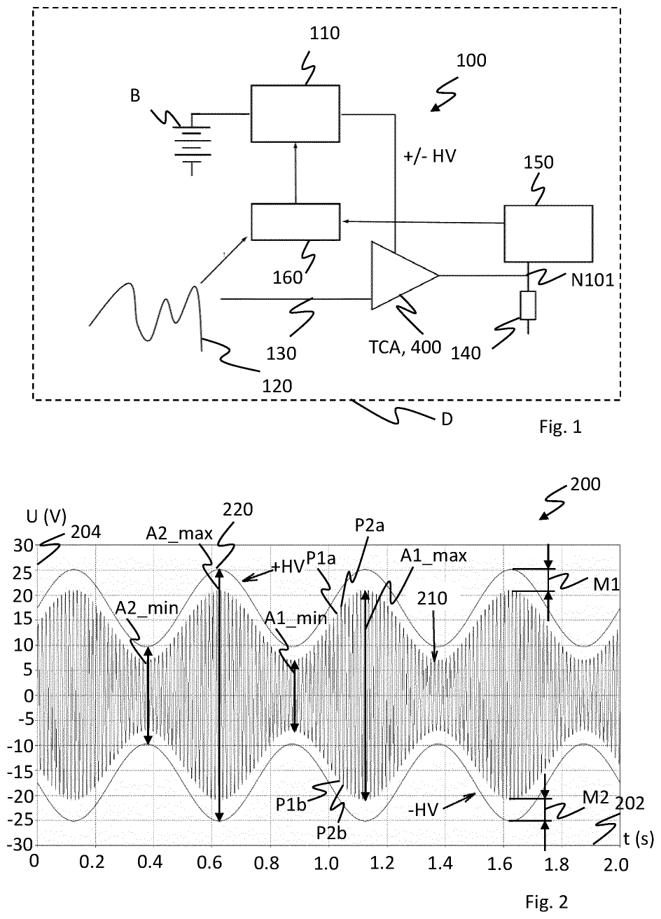

FIG. 1 a system overview of a power supply generation using signal estimation for a brain current stimulator device,

FIG. 2 an output voltage waveform and a programmed power supply voltage curve,

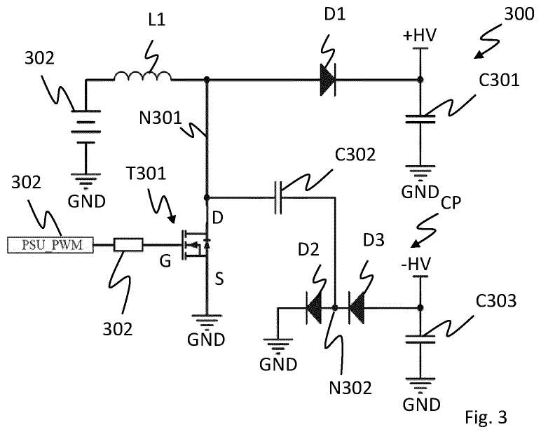

FIG. 3 a boost converter,

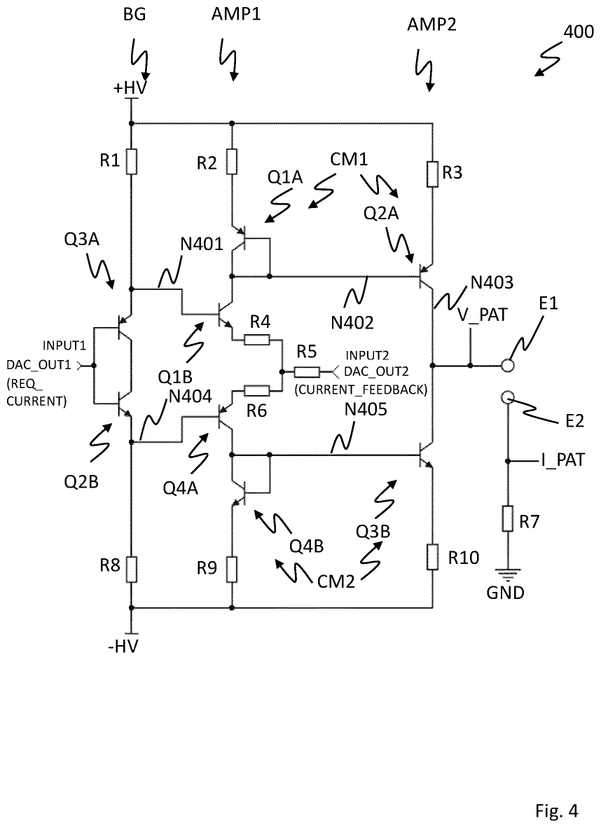

FIG. 4 a trans-conductance amplifier (TCA),

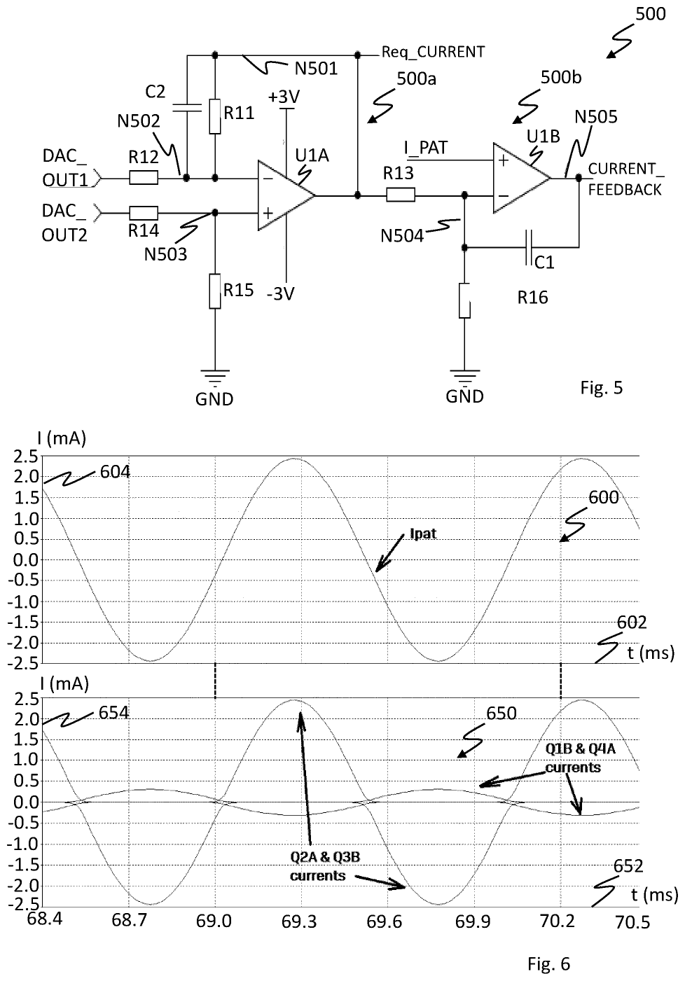

FIG. 5 a signal conditioning unit and a current control unit,

FIG. 6 resultant output currents and transistor collector currents of the amplifier,

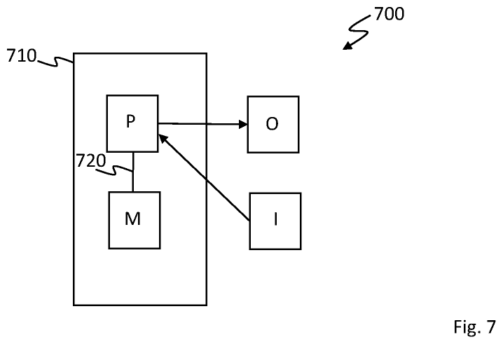

FIG. 7 a computer system that may perform the method steps which are mentioned in this document, and

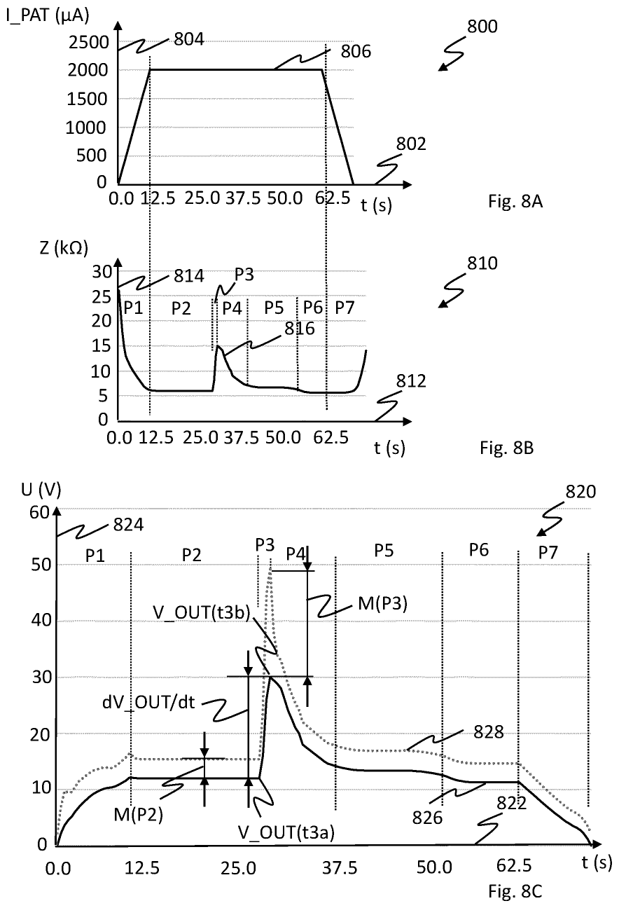

FIGS. 8A to 8C a further embodiment using constant output current or pulsed output current.

FIG. 1 illustrates a system or circuit 100 overview of a power supply generation using signal estimation for a brain current stimulator device. Circuit 100 may comprise:
a voltage converter 110 which is configured to provide at least one supply potential +HV, −HV (high voltage, for instance more than 10 Volt) depending on a control signal, PWM (Pulse Width Modulation) provided to the voltage converter 110, see for instance FIG. 3,
a control unit, e.g. processor P as illustrated in FIG. 7 or a microcontroller, which is configured to provide the control signal for the voltage converter 110,
a signal source TCA 400, see FIG. 4, which is powered by the at least one supply potential +HV, −HV and which is configured to provide an output signal at an output node N101 of the signal source TCA.

The signal source TCA may be configured to provide the output signal dependent on an input signal 120 at an input of the signal source TCA. The control unit P may comprise:
a prediction unit 160 which is configured to predict a change in the characteristic of the output signal, and
an adjusting unit 160 which is configured to adjust the control signal 302, PWM, see FIG. 3, based on the predicted change in the characteristic of the output signal.

The prediction unit 160 may be configured to predict the future value of the output signal based on a characteristic of the input signal and/or of the output signal. The second alternative is explained in more detail below.

The adjusting unit 160 may be configured to adjust the control signal 302, PWM to increase the supply voltage +HV when the predicted value indicates that the output signal V_PAT at node N101 will increase. The adjusting unit 160 may be configured to adjust the control signal 302, PWM to decrease the supply voltage +HV when the predicted voltage indicates that the output signal V_PAT at node 101 will decrease.

Circuit 100 may comprise an optional detecting unit 150. Detecting unit 150 may be configured to detect the output voltage of amplifier TCA, 400. Prediction unit 160 may be configured to predict the value or the change based on the detected output voltage or based on a characteristic value V_MEAS which is generated based on the measured output voltage. Additionally or alternatively, detecting unit 150 may be configured to detect the impedance Z of a load 140 at the output of the amplifier TCA, 400. Load 140 may be the tissue of a patient or another load. Prediction unit 160 may be configured to predict the change of the characteristic based on the detected impedance Z.

Furthermore, FIG. 1 illustrates a system 100 overview of a power supply generation using signal estimation for a brain current stimulator device D. System or circuit 100 may comprise:
a battery B, for instance lithium rechargeable battery,
a converter unit 110, for instance a HV (high Voltage, e.g. within the range of 20 Volt to 100 Volt or of 10 Volt to 50 Volt) symmetric step-up DC/DC (direct current/direct current) converter. Supply voltage HV may be unipolar, e.g. +HV and ground or bipolar, e.g. +HV, −HV and preferably ground.
a trans-conductance amplifier TCA, 400 or another appropriate amplifier,
an optional load 140, for instance formed by the tissue of a patient or of a person under treatment or training,
an optional detection unit 150 detecting or measuring load current and/or load voltage and/or impedance Z of load 140, and
a prediction unit 160, for instance a unit comprising a logic or unit for instance for tracking signal value or an envelope and/or using heuristic and/or theoretical model and/or an implicit model of changes of impedance Z of load 140.

An arbitrary stimulation signal waveform 120 may determine a desired or required output current at the output of the amplifier TCA, 400. Arbitrary stimulation signal waveform 120 may be used as an input 130 of amplifier TCA, 400 and/or as an input of prediction unit 160.

The output node N101 of amplifier TCA, 400 may be connected to a circuit node N101 which is coupled or connected to load 140 and/or to an input of detection unit 150.

An output of detection unit 150 may be connected electrically to an input of predicting unit 160. Predicting unit 160 may additionally or alternatively consider waveform 120.

An output of the prediction unit 160, especially an output of an adjusting unit within prediction unit 160 may be connected to a control input of converter unit 110. Details are described below with regard to FIG. 3.

FIG. 2 illustrates an output voltage waveform 210 and a programmed power supply voltage curve 220 which corresponds to potential +HV.

Prediction unit 160 may be configured to predict the value of change based on e.g. an alternating (oscillating) electrical signal 210 comprising a varying amplitude. A frequency of the variation of the amplitude, e.g. an envelope of the signal, may be lower than a frequency of the alternating signal 210, e.g. lower than 50 percent of the frequency of the alternating signal 210 or lower than 10 percent of the frequency of the alternating signal 210. The frequency of the envelope of signal 210 may correspond to the frequency of predicted supply voltage +HV as is illustrated by curve 220 and/or −HV.

A first electrical characteristic may relate to a first peak to peak value of the electrical signal 210 calculated based on a first maximum peak value P1a of the signal at a first time and on a first minimum peak value P1b of the signal, wherein preferably the first maximum peak value P1a is adjacent to the first minimum peak value P1b. A second electrical characteristic may relate to a second peak to peak value of the electrical signal 210 calculated based on a second maximum peak value P2a of the signal at the second time and a second minimum peak value P2b of the signal, wherein preferably the second maximum peak value P2a is adjacent to the second minimum peak value P2b.

FIG. 2 illustrates a coordinate system 200. A horizontal x-axis (abscissa) 202 illustrates the time axis in seconds, for instance in the range of 0 seconds to 2 second. A vertical y-axis (ordinate) 204 illustrates the voltage U in Volt, for instance in the range of −30 Volt to +30 Volt.

In a first variant, an output voltage signal 210 may be the resulting voltage of a similar output current which is fed or flows into the tissue of a patient using electrodes E1 and E2 mentioned later, see FIG. 4. One of the electrodes E1 or E2 may be placed at the head of the patient/person in order to stimulate brain regions. Anodal or cathodal stimulation may be applied to the electrode, e.g. E1 that is placed on the head of the person.

Thus, output voltage 210 may not be deliberately adjustable by a user but may be may result from the momentary electrical current and from the momentary electrical impedance. Output voltage signal 210 may have a first frequency of about 75 Hz (Hertz). A second frequency may relate to the periodic variation of the peak to peak value (amplitude) of alternating output voltage signal 210. The second frequency may be about 2 Hz. Other frequencies may be relevant as well.

The periodic variation of the amplitude may be intentionally programmed in the device if such modulation is considered beneficial. Another possible source of such periodic variation may be periodic changes in patient impedance, which may be caused by a multitude of biological factors such as tremors in Parkinson's disease or heartbeat impact on blood flow and thus on the impedance of the veins and/or arteries.

As is described in detail below, there may be always a sufficient margin, for instance a substantially constant margin M1 between an envelope of output voltage waveform 210 and programmed and/or generated supply potential +HV which corresponds to a supply voltage +HV, see curve 220. If a bipolar supply voltage is used, there may be always a sufficient margin M2 between an envelope of output voltage waveform 210 and programmed and/or generated supply voltage −HV. The envelope may correspond to the variation of peak to peak values, e.g. of the amplitude, of the high frequency part of output voltage waveform 210. The margin M1 and/or M2 may results in very efficient power usage as only such a power is generated which is needed by amplifier TCA, 400 an/or by overall circuit 100.

An inadequately low margin may result in a risk of signal deterioration, such as loss of precision, deviation from pre-defined value or distortion of the waveform, such as flat-top of a sine wave.

An excessively high margin may result in a loss of energy due to excess power dissipated in TCA.

A well-balanced approach to minimizing the margin while not compromising the waveform should be expected in a practical implementation. A more precise and more sophisticated prediction directly impacts the effectiveness of the method described herein.

As is visible from FIG. 2, curve 220 may have the same frequency as the envelope, e.g. the variation of the peak to peak amplitude of signal 210, i.e. about 2 Hz in the example.

Other frequencies of the envelope may be relevant as well. FIG. 2 illustrates:
a maximum amplitude A1_max of signal 210,
a minimum amplitude A1_min of signal 210,
a maximum amplitude A2_max of the difference of supply voltage +HV minus −HV,
a minimum amplitude A2_min of signal of the difference of supply voltage +HV minus −HV.

As is evident from FIG. 2, the amplitude of the difference of the supply voltages +HV minus −HV is adapted to the amplitude of the signal 210 at the output of the amplifier 400 or of signal source TA. The adaption is based on a prediction of the amplitude of signal 210. This prediction will also work similar or identical for other signal forms, e.g. alternating current or alternating voltage with constant amplitude, which may however be selected within a range, for instance within a range of 0 mA to 20 mA. Power supply voltage +HV and/or −HV is constant in this case but is automatically adapted if the amplitude of the alternating current having a constant amplitude is adjusted to another value, for instance by a user/person or patient of device D.

Even an embodiment using constant current (DC, direct current) may profit from the disclosed invention, for instance if the amount of current may again be selected within a range, for instance within a range of 0 mA to 20 mA. Power supply voltage +HV and/or −HV is constant in this case but is automatically adapted by circuit 100 if the amount or the value of the constant current is adjusted to another value, for instance by a user/person or patient of device D.

Furthermore, the envelope may have a non-periodic curve, e.g. a random noise curve. Furthermore, the circuit may also provide its technical effects if a constant output current/voltage is generated and/or it load 140 is varying over time.

In a second variant, FIG. 2 describes signal 210 for a case in which constant amplitude current is applied to the brain of a person or patient and in which case the impedance Z is changing with a frequency of e.g. 2 Hz resulting in a corresponding change of voltage output signal 210. This may be a realistic case, e.g. dependent on heart rate. However, load varying may occur usually with varying or randomly frequencies. However, the operation principles of the invention are the same in both variants.

FIG. 3 illustrates a boost converter/voltage converter 300. Voltage converter 300 may comprise:
a switching transistor T301, preferably a MOSFET,
an inductor L1, one terminal of the conductor L1 may be connected to a power source 302, for instance battery B, and the other terminal of the inductor L1 may be connected to a first circuit node N301 which may be connected to a first doped area D of the switching transistor T301,
a first diode, the anode of the first diode D1 may be connected to the first circuit node N301 and the cathode of the first diode D1 may be connected to a positive power rail +HV, and
a first capacitor C301, one electrode of the first capacitor C301 may be connected to the cathode of the first diode D1.

Voltage converter 300 may comprise a charge pump CP to generate the negative potential −HV. Charge pump CP may comprise:
a second capacitor C302, wherein preferably one electrode of the second capacitor C302 may be connected to the first circuit node N301,
a second diode D2 and a third diode D3, wherein the anode of the second diode D2 may be connected to the cathode of the third diode D3 forming a second circuit node N302 which may also be connected to the other electrode of the second capacitor C302, and
a third capacitor C303, wherein preferably one electrode of the third capacitor C303 may be connected to the anode of the third diode D3 forming a negative power rail −HV.

The following parts may be connected to ground potential:
negative terminal of power supply 301,
second electrode of capacitor C301,
source S of transistor T301,
cathode of diode D2, and
second electrode of capacitor C303.

A control signal 302 may be used which is connected to a first terminal of a resistor 302. The other terminal of resistor 302 may be connected to the Gate G of transistor T301.

The following formula may be valid for converter 300:

UA=1/(1−D)*UE (0)

wherein:
UA is the supply voltage, e.g. +HV,
UE is the input voltage, e.g. the voltage generated by battery B, for instance 3.3 Volt, and
D is the duty cycle or the pulse width of the PWM (pulse width modulation) signal 302.

The control unit, for instance processor P as illustrated in FIG. 7, may adjust the pulse width (duty cycle) of signal 302 based on the predicted or estimated voltage V_PROG which is mentioned in formula (1), see first part of the description.

Transistor T301 may have an integrated or a separate diode between its source region S and its drain region D. Furthermore, the channel substrate of transistor T301 may be connected to the source region S. The principal operation of voltage converter 300 is evident from the circuitry scheme. Thus, a detailed description is omitted here.

Other switching elements may be used instead of transistor T301, for instance a bipolar transistor or a diode. Alternatively, other voltage converters may be used, e.g. more sophisticated voltage converters.

FIG. 4 illustrates a TCA 400 which may be used for instance as signal source TA, see FIG. 1. TCA 400 may operate according to the following formula/equation:

I_{PAT}=gm*(V_{INPUT1}−V_{INPUT2}) (5)
where:
I_{PAT} is the output current,
gm is a conductance value, preferably within the range of 0.5 mS to 10 mS or in the range of 0.75 mS to 5 mS,
V_INPUT1 is a first input signal on a non-inverting input node INPUT1 of the amplifier 400, and
V_INPUT2 is a second input signal on an inverting input node INPUT2 of the amplifier, 400.

Trans-conductance amplifier TCA 400 may comprise:
a bias generating unit BG,
a first amplifier stage AMP1, preferably at least one input of the first amplifier stage AMP1 may be connected to at least one output of the bias generating unit BG, and
a second amplifier stage AMP2, preferably at least one input of the second amplifier stage AMP2 may be connected to at least one output of the first amplifier stage AMP1, preferably via at least on current mirror unit CM1, CM2.

In a first variant (variant 1) no current control (closed loop) may be used. The two input nodes INPUT1, INPUT2 may be connected directly with a differential input signal DAC_OUT1, DAC_OUT2 which is provided by the control unit, see processor P which is illustrated in FIG. 7.

Bias generation unit (branch) BG may comprise:
a resistor R1,
a bipolar transistor Q3A (letter “A” may indicate a pnp (p-n-p doped) transistor),
a bipolar transistor Q2B (letter “B” may indicate a npn (n-p-n doped) transistor), and
a resistor R8.

One terminal of resistor R1 may be connected to supply voltage +HV. The other terminal of resistor R1 may be connected to an emitter of transistor Q3A and this connection may form a circuit node N401. The collector of transistor Q3A may be connected to the collector of transistor Q2B. The emitter of transistor Q2B may be connected to a first terminal of resistor R8. This connection may form a circuit node N404. The other terminal of resistor R8 may be connected to negative supply voltage −HV. The basis of transistor Q3A may be connected with the basis of transistor Q3B forming a non-inverting input node INPUT1 of the amplifier.

First amplifier stage (branch) AMP1 may comprise:
a resistor R2,
a bipolar transistor Q1A,
a bipolar transistor Q1B,
a resistor R4 and a resistor R6,
a bipolar transistor Q4A,
a bipolar transistor Q4B, and
a resistor R9.

One terminal of resistor R2 may be connected to supply voltage +HV. The other terminal of resistor R2 may be connected to an emitter of transistor Q1A. The collector of transistor Q1A may be connected to its basis and to a circuit node N402. Furthermore, a collector of transistor Q1B may be connected to circuit node N402. An emitter of transistor Q1B may be connected to a first terminal of resistor R4. The other terminal of resistor R4 may be connected to a first terminal of a resistor R6. The second terminal of resistor R6 may be connected to an emitter of transistor Q4A. The collector of transistor Q4a may be connected to a node 405. Node 405 may be further connected with the collector of transistor Q4B and with the basis of transistor Q4B. The emitter of transistor Q4B may be connected to a first terminal of resistor R9. The other terminal of resistor R9 may be connected to negative supply voltage −HV. One terminal of a resistor R5 may be connected to the terminals of resistor R4 and R6 which are connected with each other. The other terminal of resistor R5 may form an inverting input INPUT2 of amplifier 400. The basis of transistor Q1B may be connected to node N401. Node N404 may be connected to the base of transistor Q4A.

The second amplifier stage (branch) AMP2 may comprise:
a resistor R3,
a bipolar transistor Q2A,
a bipolar transistor Q3B, and
a resistor R10.

One terminal of resistor R3 may be connected to supply voltage +HV. The other terminal of resistor R3 may be connected to an emitter of transistor Q2A. The collector of transistor Q2A may be connected to the collector of transistor Q3B. The emitter of transistor Q3B may be connected to a first terminal of resistor R10. The other terminal of resistor R10 may be connected to negative supply voltage −HV. Node N402 may be connected to the basis of transistor Q2A. Node N405 may be connected to the basis of transistor Q3B. The connection between the collectors of transistors Q2A and Q3B may form the output node of amplifier 400. The output node may be connected to a first electrode E1. A potential V_PAT may be measured at the output node, for instance by detecting unit 150.

An electrode E2 may be connected to a first terminal of a resistor R7. A second terminal of resistor R7 may be connected to ground potential. A voltage signal representing the output current I_PAT may be measured at the first terminal of resistor R7, for instance by detecting unit 150.

A first current mirror CM1 may be formed by transistors Q1A (letter “A” may indicate a pnp (p-n-p doped) transistor) and Q2A. A second current mirror CM2 may be formed by transistors Q4B (letter “B” may indicate a npn (n-p-n doped) transistor) and Q3B.

The principal operation of voltage converter 300 is evident from the circuitry scheme. Thus, a detailed description is omitted here. The overall function of amplifier 400 is described below in more detail, see section 9. According to a first variant/embodiment a signal DAC_OUT1 is fed directly into an input INPUT1 of amplifier 400. A signal DAC_OUT2 is fed directly into an input INPUT2 of amplifier 400. Thus, the circuitry which is illustrated in FIG. 5 is not used in the first variant.

In both variants 1 and 2, Wilson current mirrors may be used instead of current mirrors CM1 and CM2, using for instance a cascoding of transistors in the output branch of the Wilson current mirror (AMP2) and using a transistor in the input branch (AMP1) of the Wilson current mirror for setting the operation point.

Alternatively, other amplifiers may be used, e.g. an amplifier using CMOS technique and/or an amplifier having unipolar power supply, e.g. only +HV and ground, and/or having unipolar output voltage. It is possible to use a transimpedance amplifier depending on the application field. The generation of the varying power supply will be similar in all cases.

FIG. 5 illustrates a further circuit part 500 comprising a signal conditioning unit 500a and a current control unit 500b for a second variant/embodiment of the TCA 400 illustrated in FIG. 4. Thus, circuit 100 may comprise voltage converter 300, amplifier 400 and circuit 500.

Current control unit 500b may be provided for controlling the current at the output of the signal source TCA, 400 according to an electrical signal REQ_CURRENT which corresponds to a reference current I_AMP, e.g. according to an alternating reference current or according to an alternating reference current having a varying peak to peak value or varying amplitude.

Alternatively, a non-alternating reference current may be used, e.g. a constant reference current or a pulsed reference current, see for instance FIGS. 8A to 8C and corresponding description as mentioned below.

Current control unit 500b may comprise a control deviation unit U1B, e.g. an operational amplifier, which may generate an actuating signal CURRENT_FEEDBACK depending on the amount of deviation of a measured electrical signal I_PAT and depending on a signal REQ_CURRENT. Signal I_PAT may have a value corresponding to the current I_PAT through a load 140 at the output of the signal source TCA, 400. Signal REQ_CURRENT may represent the momentary value of the reference current I_AMP.

Signal conditioning unit 500a may comprise an operational amplifier U1A which may be configured to transform two input signals, preferably two input voltage signals DAC_OUT1, DAC_OUT2, to a single output signal preferably without offset, preferably to a single output voltage signal REQ_CURRENT, wherein the single output signal may correspond to a reference current I_AMP.

Thus, with reference also to FIGS. 4 and 5, in the second variant the signal source TCA, 400 may comprise a first input node INPUT1 and a second input node INPUT2 which are connected to different input signals respectively. Non-inverting input node INPUT1 may be connected to the signal which corresponds to a required or desired output current REQ_CURRENT of the signal source TCA, 400. Inverting input node INPUT2 may be connected to the signal which corresponds to the error signal CURRENT_FEEDBACK. As mentioned above, signal CURRENT_FEEDBACK may correspond to the difference between the signal corresponding to a measured current I_PAT and the signal REQ_CURRENT.

Signal REQ_CURRENT may correspond to a reference current I_AMP which is preferably equal to the required output current I_AMP of the signal source TCA, 400.

Signal conditioning unit 500a may comprise:
an operational amplifier U1A, e.g. an operational amplifier having bipolar supply voltage, for instance constant voltage of e.g. +3.3 Volt and −3.3 Volt,
resistors R11, R12, R14 and R15, and
a capacitor C2.

An output of operational amplifier U1A may be connected to a circuit node N501. An inverting input of operational amplifier U1A may be connected to a circuit node N502. A non-inverting input terminal of operational amplifier U1A may be connected to a circuit node N503.

Circuit node N501 may correspond to a voltage signal representing the required current REQ_CURRENT at the output of amplifier 400. Signal REQ_CURRENT may be fed into a first input of amplifier 400. Circuit node N501 may be further connected to a first terminal of capacitor C2 and to a first terminal of resistor R11. The second terminal of capacitor C2 and the second terminal of resistor R11 may be connected to circuit node N502. A first input terminal, see signal DAC_OUT1, may be connected to a first terminal of resistor R12. The second terminal of resistor R12 may be connected to node N502. A second input terminal, see signal DAC_OUT2, may be connected to a first terminal of resistor R14. The second terminal of resistor R14 may be connected to node N503. Node N503 may be connected to a first terminal of resistor R15. The second terminal of resistor R15 may be connected to ground potential.

Current control unit 500b may comprise:
an operational amplifier U1B, e.g. an operational amplifier having unipolar supply voltage, for instance constant voltage of e.g. +3.3 Volt and ground,
resistors R13 and R16, and
a capacitor C1.

The non-inverting input of operational amplifier U1B may be connected to voltage signal I_PAT. The non-inverting input of operational amplifier U1B may be connected to a circuit node N504. The output of operational amplifier U1B may be connected to a circuit node N505.

A first terminal of resistor R13 may be connected to node N501. The second terminal of resistor R13 may be connected to circuit node N504. A first terminal of resistor R16 may be connected to node N504. The second terminal of resistor R16 may be connected to ground potential. A first terminal or electrode of capacitor C1 may be connected to node N504. The second terminal or electrode of capacitor C1 may be connected to node N505. Node N505 may correspond to a voltage signal which indicates a CURRENT_FEEDBACK signal. The CURRENT_FEEDBACK signal may be fed into a second input INPUT2 of amplifier 400.

The function of additional circuit 500 is described below in more detail, see section 9.

FIG. 6 illustrates resultant output current I_PAT and transistor collector currents of transistors Q2A and Q3B and transistors Q1B and Q4A of the amplifier 400.

FIG. 6 illustrates a first coordinate system 600. A horizontal x-axis (abscissa) 602 of coordinate system 600 illustrates the time axis in ms (milliseconds), for instance in the range of 68.4 ms seconds to 70.5 ms. A vertical y-axis (ordinate) 604 of coordinate system 600 illustrates the current I_PAT in mA (milliampere), for instance in the range of −2.5 mA to +2.5 mA.

Furthermore, FIG. 6 illustrates a second coordinate system 650. A horizontal x-axis (abscissa) 652 of coordinate system 600 illustrates the time axis in ms (milliseconds), for instance again in the range of 68.4 ms seconds to 70.5 ms. A vertical y-axis (ordinate) 654 of coordinate system 650 illustrates the current through the emitter collector paths of the respective transistors in mA (milliampere), for instance in the range of −2.5 mA to +2.5 mA.

As is apparent from coordinate system 600, current I_PAT has a frequency of about 75 Hz, e.g. a time for one period of about 1.33 ms. The amplitude of current I_Pat may also vary periodically. The variation of the amplitude of I_Pat may be a deliberately programmed envelope, e.g. in case of amplitude modulated tACS (transcranial alternating current stimulation, see for instance e.g. https://doi.org/10.1016/j.neuroimage.2015.10.024 (Mapping entrained brain oscillations during transcranial alternating current stimulation (tACS), Witkowski, et. al., Neurolmage, volume 140, 15 Oct. 2016, pages 89-98). This document is enclosed by reference for all purposes.

Thus, FIG. 2 may depict amplitude modulated tACS (e.g. according to Witkowski, et. al., https://doi.org/10.1016/j.neuroimage.2015.10.024) with e.g. 75 Hz carrier frequency and e.g. 2 Hz envelope frequency. In case of constant load and am-tACS (amplitude modulated tACS) the voltage may behave in the same manner as is apparent from FIG. 2. Thus, the proposed design may be beneficial for example for stimulators having this type of functionality, as it could optimize power consumption through signal cycles.

However, a similar graph (note that it has voltage on Y-axis, not current) will depict another example of constant amplitude tACS, e.g. 75 Hz, in case of load varying with frequency, e.g. of 2 Hz. This may be a rather ideal case, as usually there will be changes of load with random frequencies and amplitudes. Anyway, the proposed invention would work similar in both conditions—as both take advantages of the adjustment of supply voltage for power optimization.

So actually FIG. 2 could be depicted in a more random way. A main intention may be this capability to adjust to random load changes. However, the principle of the invention works similarly well for AM-tACS or for other types of signals, wherein the amplitude may vary over time.

Another example is presented on FIG. 8A to 8C, which represent DC (direct current) current stimulation signal (tDCS—transcranial direct current stimulation) and load varying over time. The system may calculate V_PROG to provide margin M1 according to the equations provided earlier in the description. However, some modifications may be necessary:
dV_OUT may refer to a voltage change within a rising signal flange or within a falling signal flange, see description of FIG. 8 below (section 10),
V_MEAS may refer to a measured voltage change, and
V_CALC may refer to a calculated voltage change.

As is apparent from FIG. 6, coordinate system 650, current I_Pat is the result of the superposition of output currents of transistors Q2A and Q3B. Currents of transistors Q2A and Q3B are a scaled-up version of the collector currents of transistors Q1B and Q4A under consideration of opposite directions of electrical currents. Furthermore, it is visible that a moderate AB mode is used stage AMP2 of amplifier 400. Stage AMP1 may also comprise a class AB amplifier. Alternatively, class B amplifiers may be used in at least one stage AMP1, AMP2 or in both stages AMP1, AMP2.

FIG. 7 illustrates a computer system 700 that may perform the method steps which are mentioned in this document. Computer system 700 may be an embedded system which may be part of a brain stimulation device D. System 700 may comprise:
a computer device 110,
an optional input device 1, for instance one key, several keys, a keypad, a computer mouse and/or a data receiving unit (e.g. via internet or intranet), that is configured to input data that will be stored in a memory M, and
an optional output device O, for instance a display device (e.g. a touch screen) or a data sending unit (e.g. via internet or intranet), that is configured to output data that is generated during the execution of the instructions.

Computer device 710 may comprise:
a processor P configured to execute instructions of a program, especially for performing the disclosed method steps,
a memory M that is configured to store the instructions and to store data that is used or generated during the execution of the instructions. Memory M may include non-volatile memory and/or volatile memory.
at least one computer program product stored in memory M, for instance a BIOS (Basic Input Output System) may be part of an OS (Operation System) and/or a Firmware FW which implements the method steps mentioned in this application or at least a part of these method steps.

There may be a bus 720 between processor P and memory M. Further units of computer device 710 are not shown but are known to the person skilled in the art, for instance a power supply unit, an optional internet connection, etc. A constant power supply may be used for computer device 700.

The prediction unit 160/processor P may be configured to predict the value based on a characteristic value V_MEAS of the detected output voltage and based on a calculated characteristic value of the output voltage V_CALC, calculated preferably based on the detected impedance Z and on a known value of a maximum amplitude of an electrical current I_AMP through the load 140 at the output of the amplifier TCA, 400, preferably using the following formula:

V_{OUT}=MAX(|V_{MEAS}|,|V_{CALC}|) (2)

Furthermore, the prediction unit 160/processor P may be configured to consider a change of an output signal voltage or change in voltage amplitude (value) dV_OUT, preferably of a detected output signal voltage V_MEAS and/or of a calculated output signal voltage V_CALC, at the output of the signal source TCA, 400, preferably according to the following formula:

$${V}_{LA} = MAX ( \vert {k}_{LA} * \frac{{dV}_{OUT}}{dt} \vert , 0 ) \qquad ( 3 )$$

Moreover, the prediction unit 160/processor P may be configured to calculate a supply voltage HV, V_PROG value according to the following formula(s):

V_{PROG}=(1+kₚ)*(V_{OUT}+V_{SAT})+V_{LA} (1)

V_{CALC}=Z*I_{AMP} (4)

As mentioned above, the prediction unit 160 may be implemented using a microcontroller or a processor, for instance processor P (microprocessor). Therefore, processor P may be used to calculate the values of the left sides of formulas (1) to (4). The meaning of the variables used in formulas (1) to (4) is explained in the first part of the description and in the claims.

Processor P and circuit 100 may be used to perform the following method:
providing a voltage converter 110, 300 which generates a supply voltage +HV, −HV dependent on a control signal 302, PWM,
providing a signal source TCA, 400 which is powered by the supply voltage +HV, −HV,
   wherein the signal source TCA, 400 generates an output signal I_PAT dependent on an input signal DAC_OUT1, DAC_OUT1; REQ_CURRENT, CURRENT_FEEDBACK,
   predicting a change of a characteristic of the output signal I_PAT, and
   adjusting the control signal 302, PWM dependent on the predicted change.

A non-transitory computer readable medium M may have stored therein instructions that are executable to cause a control unit/processor P to perform at least a part of or the method mentioned in this document. A computer program product may comprise machine readable instruction which when executed on control unit/processor P cause the control unit/processor P to perform at least a part of or the method. The processor may be comprised within a microcontroller which comprises further peripheral components, e.g. DAC.

Spoken with other words, an envelope tracking for power optimization in current stimulation of tissue is proposed.

### 1. IDEA

A digitally controlled preferably symmetrical power supply generation based on signal-envelope tracking for e.g. a brain current stimulator is provided.

As is illustrated in FIG. 1 it is a main focus to achieve a minimization of the supply voltage for a TCA, 400 in case of arbitrary output signal and/or changing impedance between output electrodes. This is done by means of forecasting the envelope. Impedance is a value characterizing the relationship between current and voltage in alternating current (AC) circuits. Furthermore, we disclose a design of a TCA, 400 with closed loop current control, which is beneficial for overall performance.

### 2. SPECIAL ISSUES

Electrical stimulator (preferably trans-conductance amplifier TCA having a constant or a nearly constant trans-conductance factor gm (linear-mode) via a broad frequency range), preferably a linear-mode voltage input, current source output stimulator. There may be an arbitrary or undetermined electrical current waveform, e.g. alternating current, direct current, random pattern current, sequence of electrical current pulses, rectangular, triangular or trapezoid waveforms, and continuously-adjusting power supply voltage for biological tissue, e.g. brain, stimulation.
Digitally controlled, continuously variable voltage SMPS (Switched Mode Power Supply), tracking the expected output voltage envelope, e.g. multiplication (product) of generated momentary current signal envelope and a varying load impedance, see formula (4) mentioned for instance below. The value of the momentary current signal may be multiplied by the load variation once within a determined time window, in particular within a time window which corresponds to a signal period of a periodic signal, see for instance FIG. 6, signal 210. An offset value may be used which is a percentage of momentary signal value or which has a constant value, etc. Some voltage margin may be required, e.g. some percentage above the calculated desired values.
A simple and efficient step-up SMPS (Switched Mode Power Supply) may be used which outputs on its voltage/potential rails a symmetrical positive/negative voltage/potential using a single digitally-generated PWM (Pulse Width Modulation) signal, allowing a high dynamic range of a nearly continuously or of a continuously variable symmetrical positive/negative rail voltage.
Adaptive/predictive control of power supply voltage for linear-mode TCA stimulator, using theoretical or heuristic models of stimulated tissue impedance as a function of current amplitude, waveform and time elapsed.
Heuristic model example 1: it has been observed that patient impedance tends to first increase and then fall and stabilize during stimulation, in particular this has been proven for DC (Direct Current) stimulation. It is not uncommon to observe 10 KOhm (Kiloohm) initial impedance, jumping to an impedance value within the range of 12 KOhm to 15 KOhm during several seconds of fade-in and gradually decreasing to about 4 KOhm after 40 s to 60 s (seconds) of for instance 2 mA (milliampere) DC stimulation.
Heuristic model example 2: it has been observed, that patient impedance tends to settle at lower values for higher stimulation amplitudes (in steady state).
A high-PSRR (Power Supply Rejection Ratio), high power supply range, low-saturation voltage, class B (operation point on intersection of horizontal axis and characteristic input output curve of amplifier, value 0 Volt, push-pull, differential mode) or class AB (operation point on characteristic input output curve of amplifier, for instance on increasing portion of characteristic curve, push-pull, differential mode) e.g. not on horizontal axis) constant transconductance factor gm circuitry generating an arbitrary or undetermined current waveform in proportion to signal driving voltage.
A highly integrated mixed analog/digital system comprising of PWM generation, DC/DC power converter control, patient measurements, signal generation and a power-efficiency-maximizing feedback/feedforward loop.

### 3. EXAMPLE

FIG. 2 illustrates an example for a signal 210. Signal 210 corresponds to the output voltage waveform applied to the head of a patient. Signal 210 is an alternating voltage signal which results from a varying amplitude (for instance varying with a frequency of about 2 Hz) alternating current of a specific frequency of for instance about 75 Hz. The varying amplitude of the voltage signal may result from varying amplitude of a current signal and/or from varying load and/or may have other reasons.

Patient current: varying amplitude alternating current AC of maximum amplitude of for instance 2 mA (milliampere), other values in the range of 1 mA to 10 mA may also be used.

Alternatively, a constant amplitude alternating current AC may be used. Furthermore, a constant current may be used. In both cases the power supply voltage may be adapted based on the selected amplitude of the alternating current or of the constant current in order to provide power efficiency.

Patient impedance: slowly changing for instance in an approx. 3 KOhm (Kiloohm) to 11 KOhm range.

Patient voltages: exemplary varying in the range of about −20 Volt to +20 Volt, or within other ranges, for instance in the range of about −30 Volt to 30 Volt or in the range of −50 Volt to 50 Volt.

Power supply voltages HV (high voltage): exemplary varying in the range of about −20 Volt to +20 Volt, or within other ranges, for instance in the range of about −30 Volt to +30 Volt or in the range of −50 Volt to +50 Volt. Positive power supply voltage may be above (envelope) of positive patient voltage for upper or positive voltage and/or may be below (envelope) negative patient voltage for lower or negative voltage.

Frequency: exemplary about 75 Hz (Hertz). Other frequencies may also be used for signal 210, for instance within the following neurological relevant ranges:
0 Hz to less than 4 Hz (Delta range),
4 Hz to 8 Hz (Theta range),
9 Hz to 13 Hz (Alpha range),
14 Hz to 30 Hz (Beta range),
30 Hz and above (Gamma range).

### 4. BRIEF DESCRIPTION/ABSTRACT

The feedback from patient measurements may allow a digitally-controlled DC/DC converter, e.g. 110, 300 to provide high voltage power supply for the linear-mode TCA, 400 circuit.

Power supply is just above the required voltage to achieve the foreseen output signal voltage.

A required high voltage power supply value is being calculated to feed for instance a linear-class AB (or B) linear constant or nearly constant transconductance factor amplifier that accepts voltage on its input and outputs current independent (within some limits) on load (wide-power-supply-range trans-conductance amplifier TCA) based on load measured impedance and/or signal envelope, possibly including a look-ahead for the envelope. Calculation of the envelope is described in more detail below.

The power supply of e.g. a symmetrical positive supply voltage +HV/negative supply voltage −HV is thus changing dynamically in response to signal envelope and/or load in a continuously variable manner.

This way the final linear-mode TCA, 400 stage is dropping very low voltage from the power supply voltages provided (i.e. has low saturation voltage), maximizing efficiency and minimizing power consumption from the battery.

### 5. EXEMPLARY APPLICATION FIELD OF THE INVENTION

There is an ongoing effort to provide precision medical tissue stimulators of high precision and low noise while consuming low amounts of power. The trend is especially pronounced in battery-powered wearable devices which are often a compromise between battery weight and size, battery life and performance.

The idea is applicable to e.g. precision, low noise, tissue electrical current stimulators such as (but not limited to) transcranial brain stimulators. While the majority of tissue stimulators still use DC (direct current) or unidirectional-pulse current (such as in tDCS (transcranial Direct Current Stimulation) treatment), other stimulation signals are more and more often proposed for research and treatment. In particular AC (alternating current) and random noise signals are seen as promising for brain stimulation.

It is generally accepted that tissue stimulators come as current output sources—rather than voltage sources, to control the amplitude of current flow through the tissues being treated (such as brain) as well as through the other tissues on the way (such as stratum corneum, dermis, subcutaneous fat tissue, bones etc.). This is most often implemented as a linear-mode TCA's based on op-amps, transistors etc. working in amplifier class B or AB.

Patient impedance is widely variable and changing in time and depends on individual characteristics, electrode design, electrodes liquid saturation, stimulation stage etc. As a result, the output signal voltage (amplitude) on the patient circuit is largely unpredictable.

This has led the analog designers to provide wide design headroom or overhead and consequently a relatively high voltage power supply voltages for the linear-mode TCA stage.

The proposed scheme is tackling the non-efficiency related to high supply voltages by dynamically adjusting the supply voltages to just enough to provide an undistorted signal, thus extending battery life and/or allowing the battery to be smaller by the estimated factor of for instance seven times. The high precision and low noise of a linear-mode TCA output may not be compromised in any way using the proposed scheme.

When applied to wearable or (especially) implantable devices, the improved efficiency also directly translates to a dramatic decrease in generated heat. The heat generated by the stimulator is a vital factor in avoiding thermal effects on a tissue, which the device may be touching or being implanted to.

Limited heat generation also enables further miniaturization of the device, which would otherwise need considerable heatsinking in a limited space.

### 6. FURTHER DETAILS

In the proposed idea the DC/DC converter may provide for instance symmetric (positive/negative) voltages for the linear-mode TCA.

Rather than providing fixed or constant bipolar voltages the required power supply voltage is calculated based on set current amplitude and/or measured patient voltage and/or impedance.

A desired power supply voltage calculation may consider the following criteria:
Power supply voltage being too high results in wasted power and thus reduced efficiency,
Power supply voltage being too low results in distortion of output patient waveform due to TCA saturation and thus a reduced therapy or experiment reliability. In an extreme case example overdriven sine wave stimulation may really be a flat-top sine signal more reminiscent of a trapezoid waveform,
Any change in conditions will result in a change in desired power supply voltage—therefore may be important for the circuit to keep up with the changes and have adequately fast settling time or preferably also have means of predicting the mentioned changes

A proposed calculation of the desired power supply voltage may be done as follows:
An expected output signal voltage (a difference between the highest and the lowest point of the AC or the peak DC) V_{OUT} may be defined as the maximum of an output signal voltage on patient which is measured directly V_{MEAS} and of a calculated output signal voltage V_{CALC}, see formula (2) mentioned above. Output signal voltage V_{CALC} may be calculated according to formula (4) as multiplication product of measured impedance (Z) and goal current amplitude I_{AMP}. e.g. momentary peak to peak value or amplitude of electrical current. A greater of the two (measured, calculated) values is taken into consideration.
A programmed power supply voltage V_{PROG} according to formula (1) must be greater than the output signal voltage V_{OUT} by some percentage margin kₚ due to measurements uncertainty and due to TCA saturation voltage V_{SAT}.
A look-ahead factor k_{LA} resulting in some look-ahead voltage V_{LA} amplitude may be taken into consideration if a change dV_{OUT} of the output signal voltage V_{OUT} is positive (programmed supply voltage going up) and preferably neglected if negative. This may be used to facilitate good settling and avoid signal distortion when going up with voltages. If voltages are determined to be going down there may be probably no reason to incorporate this factor as any power savings would be marginal, yet risk of signal distortion may be prohibitive.
A look-ahead voltage V_{LA} can be generally considered as a first time derivative of output signal voltage V_{OUT}, see formula (3).

Saturation voltage V_{SAT} may be used optionally depending on TCA properties or other factors.

Saturation voltage V_{SAT} may be a constant offset value which is independent from the momentary value of the output signal voltage and may therefore guarantee a minimum offset, for instance for small values of the determined output signal voltage V_{OUT}.

In an alternative embodiment percentage margin kₚ is optional but saturation voltage V_{SAT} is used in equation (1).

If the absolute value of the voltage amplitude decreases, V_{MEAS} and V_{CALC} will also decrease, especially the absolute value thereof. This will reduce V_{OUT} and therefore also V_{PROG} which is calculated according to formula (1).

The output signal voltage V_{OUT}, V_{MEAS} and V_{CALC} may be the difference in the maximum positive voltage (positive peak voltage) of one oscillation of the considered signal and the voltage 0 Volt during a selected time period. Alternatively, the difference between the maximum positive voltage (positive peak voltage) of one oscillation of the considered signal and the minimum negative voltage (negative peak voltage) of one oscillation of the considered signal may be measured and divided by 2. The time period may be selected appropriately, for instance based on the periodicity of the alternating current/voltage, e.g. about 75 Hz in the example of FIG. 2. Alternatively, more than one time period may be considered and a mean value of the output signal voltage V_{MEAS} and V_{CALC} within the time period for one complete oscillation may be calculated.

Measured Impedance Z may be determined by dividing a measured voltage by a measured current flow, for instance measured at the same time, measured during the same measurement time window or measured through a given measurement period.

Alternatively, in another embodiment, look-ahead voltage V_{LA} may be substituted by or extended by a heuristic model of time changes of patient impedance rather than being just the time derivative of output signal voltage.

Minimal headroom or overhead is added to compensate for analog linear-mode stage saturation voltage to avoid signal clipping as well as to allow rising of the voltage due to the dynamic character of the load impedance.

A battery B (rechargeable or non-rechargeable accumulator) may be provide a low voltage to be up-converted for the analog TCA.

The output current signal shall be programmed and it can be assumed that the shape and amplitude can be very flexible in order to include a number of currently-used potentially future-developed electrical treatment programs. The output current signal is proportional to a locally-generated voltage signal or in other words, the local voltage signal is programming the output current via a TCA. This local voltage signal may be generated digitally and may be converted to an analog signal using a DAC (Digital to Analog Converter).

Alternatively, a 2-channel DAC may generate two differential representations of the desired signal. Elsewhere in this application the signals are described as DAC_OUT1 and DAC_OUT2. Output of DAC Signal may be of a fixed/constant, variable or randomly-changing amplitude. In case of non-fixed amplitude signals the estimated future amplitude may be retrieved by the look-ahead of the incoming signal pattern.

The DC/DC converter may convert low (and positive) voltage from the battery into high bipolar voltage needed by the TCA.

TCA is designed to provide output current in proportion to input voltage. The circuit may be designed to have a very high output impedance, i.e. very low dependence of output current with load (patient) impedance while voltage is allowed to adjust accordingly.

The TCA circuit may be a class B (or AB) analog amplifier which may practically approach energy efficiency of more than 60% in a sine signal but only on the condition that power supplies are just above the undistorted peaks of the sine. In case of power supply voltage considerably above the value of the peaks of the sine the efficiency drops dramatically. In this invention this is mitigated by the dynamic power supply voltages changing as required to provide optimum efficiency of class B TCA.

Patient current/voltage/impedance measurements normally serve numerous diagnostic purposes such as indication of electrodes montage, estimation of patient sensations, safety indicators etc. In addition to those purposes in this invention the output voltage is also processed for the calculation of the DC/DC converter required output voltages V_{PROG}.

The dynamics of the system, such as an ability of HV (high voltage) supplies to rise in time shall be faster than foreseen changes in patient circuit impedance due to movement of electrodes, drying of wet electrodes or skin response.

### 7. PROPOSED EMBODIMENT

FIG. 3 depicts a simplified power conversion schematic of a symmetric DC/DC converter, e.g. a PSU (Power Supply Unit). This is a combination of a boost converter with a negative voltage charge pump circuit that assures symmetrical voltages by design.

A Pulse-Width-Modulation (PWM) signal is coming from the microcontroller and controls the value of the output voltages HV, e.g. +HV and −HV. A microcontroller (not shown) may generate the PWM signal. The microcontroller may also monitor positive HV and negative HV supply voltages and perform the envelope tracking.

FIG. 4 depicts a simplified class AB trans-conductance amplifier (TCA) 400 schematic. The circuit 400 may be operated over a wide power supply range. The function of circuit 400 is explained in more detail below, see section 9, i.e. there is a bias generator BG, a first amplifier stage AMP1 and a second amplifier stage AMP2. In a first variant, signals DAC_OUT1 and DAC_OUT2 are directly connected to the two input nodes of circuit 400.

This may result in a similar operation compared with the current controlled circuit of section 9.

The TCA 400 may have a fixed transconductance factor gm.

The relationship between output current and input differential voltage may be given by:

I_{PAT}=gm*(V_{DAC_OUT1}−V_{DAC_OUT2}) (5)
where:
I_{PAT} is the output current,
gm is a conductance value,
DAC_OUT1 is an output signal of a first DAC output or of a first DAC and is used as input for the amplifier, for instance on a non-inverting input node of the amplifier 400, and
DAC_OUT2 is an output signal of a second DAC output or of a second DAC and is used as input for the amplifier, for instance on an inverting input node of the amplifier 400.

Typical values of gm may be in order of 1 mS (Milli-Siemens) to 2 mS.

An output voltage V_{PAT} or V_PAT is a product of I_{PAT} and load impedance Z.

The output current I_{PAT} to the patient is proportional to the difference of two the Digital-to-Analog-Converter (DAC) outputs, the gain gm is determined by resistors in the circuit 400 and by the multiplication ratio of the multiplying current mirrors.

As mentioned above, signals DAC_OUT1, DAC_OUT2 are calculated depending on the desired output wave form of the current I_{PAT} which corresponds to the measured current I_PAT.

The measured current I_PAT and the measured voltage V_Pat which corresponds to V_{MEAS} are used to measure or to determine or to detect the impedance Z of the load, e.g. of the tissue of a patient between two electrodes E1 and E2. The impedance Z and the measured voltage are used to determine V_{PROG} according to formulas (1) to (4) given above.

### 8. PRACTICAL HIGH-PERFORMANCE TCA CIRCUIT

A more precise or more practical implementation of the TCA circuit having a greater independence of power supply conditions (high Power Supply Rejection Ratio—PSRR), low intrinsic offset, good efficiency and acceptable thermal stability is illustrated in FIGS. 4 and 5, e.g. second variant. Precision of circuit 100 may be below 3 percent, below 2 percent or below 1 percent deviation from a desired output current. The deviation may be for instance greater than 0.5 percent in all three cases.

Note that the principle of operation is very similar to aforementioned circuit of FIG. 4. However, the performance is improved by usage of high negative feedback, e.g. by usage of a closed loop current control as illustrated in FIG. 5. The following circuit nodes are connected with each other:
FIG. 4, I_PAT and FIG. 5, I_PAT, i.e. measured current I_PAT,
FIG. 4, DAC_OUT1 and FIG. 5, REQ_CURRENT, i.e. required current,
FIG. 4, DAC_OUT2 and FIG. 5, CURRENT_FEEDBACK, i.e. control deviation of required current minus measured current.

Again, the measured current I_PAT and the measured voltage V_PAT which corresponds to V_{MEAS} are used to measure or to determine or to detect the impedance Z of the load, e.g. of the patient between two electrodes E1 and E2. The impedance Z and the measured voltage are used to determine V_{PROG} according to formulas (1) to (4) given above.

This current-feedback results in a nearly-perfect TCA outputting current independent on the load.

The current feed-back may be applied especially in applications in the medical field or in application in the health care system. However, other application fields are possible as well, for instance radio communication, e.g. within wireless or wireline telecommunication networks, radio broadcast stations or television broadcast stations to mention only some of the potential application areas.

Also, the TCA main circuitry works from +/−HV supply, which may dynamically change in a wide range of voltages.

The HV supplies may typically be up to around +/−50V for typical application, however the circuit can be easily scaled-up (with little or no modifications) so that even higher HV voltages are possible. General circuit topology may also be used as a starting point for integration into a single silicon chip IC (Integrated Circuit) using for instance bipolar transistors or CMOS (Complementary Metal (or highly doped semiconductor) Oxide Semiconductor) transistors or mixed transistors on a single silicon die forming an IC (Integrated Circuit).

Op-amps (Operational Amplifiers) are supplied from a lower operation voltage such as +/−3.3V or similar. Suitable op-amps may be of rail-to-rail input/output type and/or of gain-bandwidth product (>1 MHz) for best performance.

### 9. DETAILED DESCRIPTION OF HIGH-PERFORMANCE TCA

The following description is given without to be bound by theory. The initial signal conditioning may be designed so that a unipolar voltage signal such as swinging between 0 V and +3.3 V, i.e. there is signal offset, out of differential-output DAC is converted to a bipolar signal, such as swinging between −3.3 V to +3.3 V.

It is assumed that inputs DAC_OUT1 and DAC_OUT2 are either:
a) one differential output from a dual-channel DAC, or
b) one active DAC output, for instance within the range of 0 Volt to +3.3 Volt and a constant reference output e.g. +1.65V.

The a) case of differential DAC output may be desirable due to reduced noise (common noise reduction) or to increase an effective DAC resolution by 1 bit.

The b) case of a single DAC output and a constant reference is an easier to implement option and potentially a cheaper option.

As is illustrated further in FIG. 5, a first stage of control circuitry 500 comprises a signal conditioning unit 500a. Signal conditioning unit 500a comprises an operational amplifier U1A, resistors R12, R14, R11, R15 and a capacitor C2 and provides such transposition or signal conditioning from two differential DAC_OUT1 and DAC_OUT2 signals, e.g. case a) as mentioned above (or 1 signal and 1 offset, e.g. case b) as mentioned above) to one single-ended signal without offset.

The signal transposition for case a) may be for instance as follows:

3.3 Volt minus −3.3 Volt=6.6 Volt,

1.65 Volt minus −1.65 Volt=3.3 Volt,

0 Volt minus 0 Volt=0 Volt.

A scaling factor may be used for a further transformation to the desired voltage range.

The signal transposition for case b) may be for instance as follows:
0 Volt plus minus 1.65 Volt is equal to −1.65 Volt.
1.65 Volt minus 1.65 Volt is equal to 0 Volt.
3.3 Volt minus 1.65 Volt is equal to +1.65 Volt.

A scaling factor may be used for a further transformation to the desired voltage range.

It may generally be assumed that R12=R14 and R11=R15 to perform a full differential amplifier function. Capacitor C2 provides some low-pass filtering for DAC (Digital Analog Converter) reconstruction and might be required to ensure stability, but generally should be considered optional. Output from differential amplifier is called REQ_CURRENT in this example. If the voltage signal source is already referenced to and swinging around zero this stage may be skipped.

The REQ_CURRENT voltage signal may be fed into a bias generator BG consisting of Q3A (“A” may stand for a npn (n-p-n doped) bipolar transistor), Q2B (“B” may stand for a pnp (p-n-p doped) bipolar transistor), R1 and R8. This stage BG provides two signals higher than and lower than REQ_CURRENT by approximate 0.6 V (Volt) to 0.65 V (one bjt (bipolar junction transistor) b-e (basis-emitter diode voltage drop). R1 and R8 may force a small current flow though base-emitter-junctions of Q3A and Q2B. In a more elaborate (or IC—integrated circuit) version R1 and R8 could be replaced by constant DC current sources. The same may apply to at least one of the other resistors of amplifier 400.

Following the signals coming out of the bias generator BG they feed bases of Q1B and Q4A, which may work in class AB amplifier AMP1 mode and generate a scaled-down (in relation to Q2A and Q3B) portion of output class AB amplifier AMP1 currents through the bjt (bipolar junction transistor) collectors.

Current mirrors consisting of Q1A, R2, Q2A, R3 and Q4B, R9, Q3B, R10 provide a final conveying (and typically some scaling-up) of current from previous stage collector currents to form the patient output current. It may be designed so that R3<R2 and R10<R9 so that the current mirrors are multiplying (scaling-up) the collector currents for improved efficiency. Output transistors Q2A and Q3B typically work in class B or low-bias AB amplifier AMP2 mode (similar to Q1B and Q4B but typically at scaled-up currents) and resultant current of the collectors create output patient current I_PAT.

More elaborate/precise versions of current mirrors (such as Wilson current mirrors) may be considered as well, but typically are not necessary.

A sine patient current output is illustrated in FIG. 6. An example of current waveforms of patient (above) and output class AB transistors Q2A and Q3B and Q1B and Q4B transistors Q1B and Q4B (below) is depicted in FIG. 6.

It should be noted that quiescent (standby) current of the stages and the ratio of currents between the stages may be adjusted and typically are a trade-off between high efficiency and low (zero-crossing and high signal) distortion.

Output current flows through electrode E1, the attached load (‘patient’), electrode E2 and through sense resistor R7 back to system ground reference. Voltage drop on resistor R7 provides a sense signal proportional to the output current I_PAT. This sense signal may be used to create a feedback loop.

Sense signal I_PAT is the current flowing through the tissue of the patient.

Furthermore, as illustrated in FIG. 5, a feedback error amplifier is built around operational amplifier U1B, resistors R13 and R16 and capacitor C1. Resistors R13 and R16 set the overall transconductance ‘gain’ of the circuit (along with R7 and differential amplifier) so that a portion of REQ_CURRENT is compared against I_PAT feedback sense.

The output signal from the stage CURRENT_FEEDBACK is provided though R5 (and R4 and R6) back to emitters of Q1B and Q4A stage closing the feedback loop. Resistor R5 must or should be calculated so that full current swing is ensured and also sets the overall loop gain of the system (along with op-amp U1B open loop gain). Capacitor C1 may ensure system stability by introducing a dominant pole into a feedback loop. An additional feedback zero following dominant pole may be created as a side-effect, which typically may be considered positive for loop stability.

It should be noted that output stage current is made-up from summed outputs from current mirrors, thus providing a high output impedance in open loop. Therefore, since the circuit works as a high-output-impedance in both open loop (only FIG. 4) and closed loop (FIGS. 4 and 5), a very robust load tolerance is expected or provided. The load impedance does not appear in the loop transfer function. Neither low, high, inductive nor capacitive load affects the system stability or triggers oscillation.

Other transistors, for instance MOSFET (Metal Oxide Semiconductor Field Effect Transistor, also with doped gate) may also be used, especially if circuit 100 is realized within an IC (integrated circuit).

### 10. FURTHER EMBODIMENT—PREDICTION BASED ON CHANGE OF VALUES OF OUTPUT SIGNAL

It is worth adding, that standard tACS comprising relatively slow changes of amplitudes would benefit from the proposed invention as well because it is not necessary to keep the power supply voltage at the level of the peak amplitude, but the power supply can be adjusted for following the requirements of the signal. Relatively slow may mean frequencies of less than 1000 Hz, less than 300 Hz, less than 60 Hz or less than 10 Hz. However, the frequencies may even be higher as long as the processor may calculate the necessary calculations in time. Processors having clock frequencies of several GHz (gigahertz) are available on the market, e.g. more than 3 GHz, 4 GHz or more than 5 GHz. Thus, the proposed invention may be applied in the frequency range of:
DC (direct current, 0 KHz(kilohertz)) to 1 KHz,
0.0001 Hz (hertz) to 1 KHz,
0 KHz or 0.016 Hz (once per minute) to 10 KHz,
0 KHz or 0.0001 KHz to 100 KHz, 1 MHz (Megahertz), 10 MHz or even higher depending on the application.

The higher frequency ranges may be valid for instance for signals in analog and/or digital radio transmission or in other application areas. The same may apply for non-periodic signal changes of comparably changing “velocity” or signal raising times and/or signal falling times.

Thus, it is possible to implement a solution that is based on the values of the output signal directly and not on the envelope of the output signal. For instance, in FIG. 2 only one period of signal 210 may be regarded. If signal 210 rises or increases, the control unit P which is configured to provide the control signal for the voltage converter rises the power supply voltage. If signal 210 remains comparably constant at the turning points, the power supply voltage may be maintained constant. If signal 210 decreases, this control unit P may decrease power supply voltage or supply potential +HV/−HV. Again, an appropriate margin, e.g. M1 and/or M2 or offset may be used.

FIGS. 8A to 8C illustrate a further embodiment using constant output current or pulsed output current, e.g. pulsed output current comprising a constant plateau of the signal.

FIG. 8A illustrates a Cartesian coordinate system 800 comprising a horizontal x-axis 802 (abscissa) and a vertical y-axis 804 (ordinate). X-axis 802 illustrates time t, e.g. within the range of 0 s (seconds) to about 75 s. Y-axis 804 illustrates current I_PAT in microampere, e.g. within the range of 0 microampere to 2500 microampere (2.5 mA (milliampere)). In the embodiment a curve 806 depicts a constant current between 12.5 seconds and 62.5 s, i.e. of a duration of 50 s. There is a linear signal rising flange e.g. between 0 s and 12.5 s and a linear signal falling flange e.g. between 62.5 s to 75 s. The value of the constant current is e.g. 2000 microampere which corresponds to 2 mA). However, in other examples current impulses of different length and different current height may be used.

FIG. 8B illustrates a Cartesian coordinate system 810 comprising a horizontal x-axis 812 (abscissa) and a vertical y-axis 814 (ordinate). X-axis 812 illustrates time t, e.g. within the range of 0 seconds to about 75 seconds. Y-axis 814 illustrates varying impedance Z of the load (e.g. 140) in Kiloohm (KOhm), e.g. within the range of 0 KOhm to 30 KOhm. Impedance Z may be a complex value of a complex physical quantity.

The amplitude value of impedance Z may be as is illustrated in FIG. 8B. Thus, the phase angle may not be considered. As is apparent from FIG. 8B, curve 816 impedance Z falls within a first phase P1 from e.g. about 25 KOhm to about e.g. 6 KOhm within the time range of 0 s to about 10 s. Thereafter, impedance Z remains approximately constant within a phase P2 due to e.g. constant current 806, e.g. within the time range of 10 s to e.g. about 30 s. Due to for instance a change in tissue to which electrodes of a brain stimulator or of another stimulator are connected, there is a sharp increase in impedance Z at time t of 30 s to time t of 32 s from about 6 KOhm to about 15 KOhm, i.e. within a phase P3. As will be explained below in more detail, this increase may require an increase in supply potential or supply voltage +HV, see curve 828 in FIG. 8C.

After reaching a peak value of about 15 KOhm impedance Z may fall again back to a value of first about 7 KOhm during a time range (phase P4) starting at 32 s to 37.5 s, e.g. because of changes within the tissue. Thereafter, within a phase P5, there may be the impedance value of 7 KOhm between time t of 37.5 s to 55 s, then a slight decrease to about 6 KOhm which are hold within a phase P6 between time t of 55 s to about 65 s. At the end of the example, e.g. between 65 s to 75 s impedance Z may rise again due to the decrease of current I_PAT within this time window, see phase P7.

FIG. 8C illustrates a Cartesian coordinate system 820 comprising a horizontal x-axis 822 (abscissa) and a vertical y-axis 824 (ordinate). X-axis 822 illustrates time t, e.g. within the range of 0 s to about 75 s. Y-axis 824 illustrates the voltage in the range of 0 Volts to 60 Volt, e.g. output voltage, see curve 826 and supply voltage +HV, see curve 828.

Correspondingly to the seven phases P1 to P7 mentioned above for the changes of impedance Z there are corresponding changes for output voltage 826 and also for supply voltage +HV. Supply voltage +HV is related to output voltage 826, especially to predicted output voltage 826 via at least one margin, e.g. margin M1 and margin M2 as is described in more detail below. The phases P1 to P7 of output voltage 826 are:
Phase P1 (0 s to 10 s): output voltage 826 increases from 0 Volt to e.g. about 12 Volt,
Phase P2 (10 s to 30 s): output voltage 826 remains constant at e.g. 12 Volt,
Phase P3 (30 s to 32 s): sharp rise of output voltage 826 from e.g. 12 Volt to e.g. 30 Volt,
Phase P4 (32 s to 37.5 s): output voltage 826 decreases from 30 Volt to about 14 Volt,
Phase P5 (37.5 s to 55 s): output voltage 826 remains at approximately 14 Volt,
Phase P6 (55 s to 65 s): after a slight decrease, output voltage 826 remains at approximately 12 Volt, and
Phase P5 (65 s to 70 s): output voltage 826 decreases from 12 Volt to 0 Volt almost linearly.

The phases P1 to P7 of supply voltage 828, HV or +HV are:
Phase P1 (0 s to 10 s): voltage 828 increases from 0 Volt to e.g. about 15 Volt,
Phase P2 (10 s to 30 s): voltage 828 remains constant at e.g. 15 Volt,
Phase P3 (30 s to 32 s): sharp rise of voltage 828 from e.g. 15 Volt to e.g. about 50 Volt,
Phase P4 (32 s to 37.5 s): voltage 828 decreases from about 50 Volt to about 17 Volt,
Phase P5 (37.5 s to 55 s): voltage 828 remains at approximately 17 Volt,
Phase P6 (55 s to 65 s): after a slight decrease, voltage 828 remains at approximately 15 Volt, and
Phase P5 (65 s to 70 s): voltage 828 decreases from 15 Volt to 0 Volt almost linearly.

Output voltage, output current and impedance Z are related to each other via Ohm's Law. These relations are also apparent from FIGS. 8A to 8C.

Thus, there may be for instance a first margin M of about 3 Volt within phases P1, P2, P5 and P6, e.g. during moderate rise and during constant signal phases, see for instance margin M(P2). A higher margin M of about 10 Volt may be used in phase P3, i.e. during sharp rise, see for instance margin M(P3). Margins of less than 3 Volt may occur in phase P4 and phase P7, e.g. within phases with decreasing signal levels or voltage levels.

Output voltage 826 may have a voltage value V_OUT(t3a), V(t3a) at the beginning of phase P3 and a voltage value V_OUT(t3b), V(t3b) at the end of phase P3. The rise per time dV_OUT/dt within phase P3 may be about 18 Volt. The rise per time of supply voltage within the same time window dt or within Phase P3 may be much higher, e.g. about 35 Volt in order to make sure that the margin M(P3) is always high enough. Control of supply voltage 828 may be based on time windows which are much shorter than phase P3, e.g. within time windows of less than 50 milliseconds or less than 20 milliseconds depending from e.g. the expected “velocities” of signal changes of output signal 826. This will reduce dV_OUT considerably and will allow very good prediction of changes of output voltage, see curves 826 and 828.

Thus, all three coordinate systems 800, 810 and 820 refer to the same embodiment and are related to each other e.g. by referring to the same time t on time axis 802, 812 and 822.

Equations (1) to (4) may be used for the embodiment illustrated in FIGS. 8A to 8C. The following modifications may be necessary:
dV_OUT may refer to a voltage change within a rising signal flange or within a falling signal flange, see description of FIG. 8 below (section 10),
V_MEAS may refer to a measured voltage change, and
V_CALC may refer to a calculated voltage change.

Although embodiments of the present disclosure and their advantages have been described in detail, it should be understood that various changes, substitutions and alterations can be made therein without departing from the spirit and scope of the disclosure as defined by the appended claims. For example, it will be readily understood by those skilled in the art that many of the features, functions, processes and methods described herein may be varied while remaining within the scope of the present disclosure. Moreover, the scope of the present application is not intended to be limited to the particular embodiments of the system, process, manufacture, method or steps described in the present disclosure. As one of ordinary skill in the art will readily appreciate from the disclosure of the present disclosure, systems, processes, manufacture, methods or steps presently existing or to be developed later that perform substantially the same function or achieve substantially the same result as the corresponding embodiments described herein may be utilized according to the present disclosure. Accordingly, the appended claims are intended to include within their scope such systems, processes, methods or steps. The embodiments mentioned in the first part of the description may be combined with each other. The embodiments of the description of the Figures may also be combined with each other. Further, it is possible to combine embodiments mentioned in the first part of the description with examples of the second part of the description which relates to FIGS. 1 to 8C.

1. Circuit (100) for a medical device or for another electronic device, comprising:
a voltage converter (110, 300) which is configured to provide at least one supply potential (HV) depending on a control signal (302, PWM) provided to the voltage converter (110, 300),
a control unit (P) which is configured to provide the control signal (302, PWM) for the voltage converter (110, 300),
a signal source (TCA, 400) which is powered by the at least one supply potential (+HV) and which is configured to provide an output signal at an output of the signal source (TCA, 400), wherein the signal source (TCA, 400) is configured to provide the output signal dependent on an input signal (120) at an input of the signal source (TCA, 400),
wherein the control unit (P) comprises:
a prediction unit (160) which is configured to predict a change of a characteristic of the output signal based on at least one detected value of the output signal, and
an adjusting unit (160) which is configured to adjust the control signal (302, PWM) based on the predicted change in the characteristic of the output signal.

2. Circuit (100) according to claim 1, wherein the prediction unit (160) is configured to consider a change of an output signal voltage (dV_OUT) of the output signal,
wherein preferably the prediction unit (160) is configured to consider a look-ahead factor (k_{LA}).

3. Circuit (100) according to claim 1 or 2, wherein the prediction unit (160) is configured to predict the change of the output signal based on a characteristic of an electrical signal, wherein the electrical signal is the input signal or the output signal,
wherein a first characteristic relates to a first signal value of the electrical signal at a first time and a second characteristic relates to a second signal value of the electrical signal at a second time which is after the first time, preferably within the same raising or falling signal part of the electrical signal after the first time,
and wherein the prediction unit (160) is configured to predict the change of the output signal based on the first signal value and on the second signal value, preferably based on the difference of the second signal value and of the first signal value.

4. Circuit (100) according to any one of the preceding claims,
wherein the prediction unit (160) is configured to predict the change of the output signal based on a characteristic of an electrical signal,
wherein the electrical signal is the input signal or the output signal,
wherein a first characteristic or the first characteristic relates to a first signal value of the electrical signal at a first peak (P1a) of the electrical signal at a first time and a second characteristic or the second characteristic relates to a second signal value of the electrical signal at a second peak (P2a) of the electrical signal at a second time which is after the first time, preferably within the next oscillation of the electrical signal after the first time,
and wherein the prediction unit (160) is configured to predict the change of the output signal based on the first signal value and on the second signal value, preferably based on the difference of the second signal value and of the first signal value.

5. Circuit (100) according to claim 4, wherein the first characteristic relates to a first peak to peak amplitude value of the electrical signal calculated based on a first maximum peak value (P1a) of the electrical signal at the first time and on a first minimum peak value (P1b) of the electrical signal, wherein preferably the first maximum peak value (P1a) is adjacent to the first minimum peak value (P1b), and
wherein the second characteristic relates to a second peak to peak amplitude value of the electrical signal calculated based on a second maximum peak value (P2a) of the electrical signal at the second time and a second minimum peak value (P2b) of the electrical signal, wherein preferably the second maximum peak value (P2a) is adjacent to the second minimum peak value (P2b).

6. Circuit (100) according to any one of the preceding claims, wherein the adjusting unit (160) is configured to adjust the control signal (302, PWM) to increase the supply voltage (HV) when the predicted change indicates that the output signal (V_PAT) will increase or the amplitude of the output signal (V_PAT) will increase, and
wherein the adjusting unit (160) is configured to adjust the control signal (302, PWM) to decrease the supply voltage (HV) when the predicted change indicates that the output signal (V_PAT) or the amplitude of the output signal (V_PAT) will decrease, and/or
wherein the prediction unit is configured to predict the change based on an alternating electrical signal comprising a varying amplitude, wherein preferably a frequency of the variation of the amplitude is lower than a frequency of the variation of the alternating signal itself, e.g. lower than 50 percent of the frequency of the alternating signal or lower than 10 percent of the frequency of the alternating signal.

7. Circuit (100) according to any one of the preceding claims, wherein the circuit (100) comprises a detecting unit (150),
wherein the detecting unit (150) is configured to detect the output voltage of the signal source (TCA, 400), and
wherein the prediction unit (160) is configured to predict the change based on the detected output voltage or based on a characteristic value (V_MEAS) which is generated based on the measured output voltage, and/or
wherein the detecting unit (150) is configured to detect the impedance (Z) of a load (140) at an output of the amplifier (TCA, 400), and
wherein the prediction unit (160) is configured to predict the change based on the detected impedance (Z).

8. Circuit (100) according to claim 7, wherein the prediction unit (160) is configured to predict the change of the output voltage based on a characteristic value (V_MEAS) of the detected output voltage and based on a calculated characteristic value of the output voltage (V_CALC), calculated preferably based on the detected impedance (Z) and on a known value of an electrical current (I_AMP) through the load (140) at the output of the amplifier (TCA, 400),
preferably using the following formula:
V_{OUT}=MAX(|V_{MEAS}|,|V_{CALC}|) (2)
where:
V_{MEAS} is the measured output signal voltage or the voltage amplitude of the output signal,
V_{CALC} is a calculated output signal voltage or the voltage amplitude of the output signal, and
MAX is the maximum function.

9. Circuit (100) according to any of the claim 7 or 8, wherein the prediction unit (160) is configured to consider a change of an output signal voltage (dV_OUT), preferably of a detected output signal voltage (V_MEAS) and/or of a calculated output signal voltage (V_CALC), at the output of the signal source (TCA, 400), preferably according to the following formula:
$${V}_{LA} = MAX ( \vert {k}_{LA} * \frac{{dV}_{OUT}}{dt} \vert , 0 ) \qquad ( 3 )$$
where:
dV_{OUT} is the change in the output signal voltage or the change in the voltage amplitude of the output signal during a considered time period dt,
dt is the considered time period or time frame,
k_{LA} is an optional look-ahead factor, and
MAX is the maximum function.

10. Circuit (100) according to claim 8 and 9, wherein the prediction unit (160) is configured to calculate a supply voltage (HV, V_PROG) value according to the following formula:
V_{PROG}=(1+kₚ)*(V_{OUT}+V_{SAT})+V_{LA} (1)
where:
k, is an optional percentage margin,
V_{OUT} is the output signal voltage and is calculated according to formula (2),
V_{SAT} is an optional saturation voltage, and
V_{LA} is calculated according to formula (3).

11. Circuit (100) according to any one of the preceding claims, wherein the prediction unit (160) is configured to consider an implicit model and/or a heuristic model and/or a theoretical model of the change of the impedance (Z) of a load (140) at an output of the signal source (TCA, 400) for the prediction of the change, preferably a heuristic model or theoretical model of a load (140) which is formed by the tissue of a person.

12. Circuit (100) according to any one of the preceding claims, comprising a current control unit (500b) for controlling the current at the output of the signal source (TCA, 400) according to an electrical signal (REQ_CURRENT) which corresponds to a reference current, e.g. according to an alternating reference current or according to an alternating reference current having a varying amplitude or according to a constant reference current.

13. Circuit (100) according to claim 12, wherein the current control unit (500b) comprises a control deviation unit (U1B) which generates an actuating signal (CURRENT_FEEDBACK) depending on the amount of deviation of a measured electrical signal (I_PAT) which has a value corresponding to the current (I_AMP) through a load (140) at the output of the signal source (TCA, 400) and depending on a signal (REQ_CURRENT) which represents the momentary value of the reference current.

14. Circuit (100) according to any one of the preceding claims, comprising a signal conditioning unit (U1A) which is configured to transform two input signals, preferably two input voltage signals (DAC_OUT1, DAC_OUT2), to a single output signal preferably without offset, preferably to a single output voltage signal (REQ_CURRENT), wherein the single output signal corresponds to a reference current.

15. Circuit (100) according to any one of the preceding claims, wherein the voltage converter (110, 300) comprises:
a switching transistor (T301), preferably a MOSFET,
an inductor (L1), preferably one terminal of the conductor (L1) connected to or connectable to a power source (302) and the other terminal of the inductor (L1) connected to a first circuit node (N301) which is connected with a first doped area (D) of the switching transistor (T301), a first diode, preferably the anode of the first diode (D1) connected to the first circuit node (N301) and the cathode of the first diode (D1) connected to a positive power rail (+HV), and
a first capacitor (C301), preferably one electrode of the first capacitor (C301) connected to the cathode of the first diode (D1).

16. Circuit (100) according to claim 15, wherein the voltage converter (110, 300) comprises a charge pump (CP) to generate a negative potential (−HV),
wherein the charge pump (CP) preferably comprises:
a second capacitor (C302), preferably one electrode of the second capacitor (C302) connected to the first circuit node (N301),
a second diode (D2) and a third diode (D3),
wherein the anode of the second diode (D2) is connected to the cathode of the third diode (D3) forming a second circuit node (N302) which is also connected to the other electrode of the second capacitor (C302), and
a third capacitor (C303), preferably one electrode of the third capacitor (C303) connected to the anode of the third diode (D3) forming a negative power rail (−HV).

17. Circuit (100) according to any one of the preceding claims, wherein the signal source (TCA, 400) operates according to:
I_{PAT}=gm*(V_{INPUT1}−V_{INPUT2}) (5)
where:
I_{PAT} is the output current of the signal source (TCA, 400),
gm is a conductance value, preferably within the range of 0.5 mS to 10 mS or in the range of 0.75 mS to 5 mS,
V_INPUT1 is a first input voltage on a non-inverting input node of the amplifier (TCA, 400), and
V_INPUT2 is a second input voltage on an inverting input node of the amplifier (TCA, 400).

18. Circuit (100) according to any one of the preceding claims, wherein the signal source (TCA, 400) comprises:
a bias generating unit (BG),
a first amplifier stage (AMP1), preferably at least one input of the first amplifier stage (AMP1) connected to at least one output of the bias generating unit (BG), and
a second amplifier stage (AMP2), preferably at least one input of the second amplifier stage (AMP2) connected to at least one output of the first amplifier stage (AMP1), preferably via at least one current mirror unit (CM1, CM2).

19. Circuit (100) according any one of the preceding claims, wherein the signal source (TCA, 400) comprises two input nodes (INPUT1, INPUT2) which are connected directly with a differential input signal (DAC_OUT1, DAC_OUT2), or
wherein the signal source (TCA, 400) comprises a first input node (INPUT1) and a second input node (INPUT2) which are connected to different input signals respectively, preferably a non-inverting input node (INPUT1) that is connected to a signal which corresponds to a required or desired output current (REQ_CURRENT) of the signal source (TCA, 400) and preferably an inverting input node (INPUT2) that is connected to an error signal (CURRENT_FEEDBACK) which represents the difference between a signal corresponding to a measured current (I_PAT) and a signal (REQ_CURRENT) corresponding to a reference current (I_AMP),
wherein the reference current (I_AMP) is preferably equal to the required output current (I_AMP) of the signal source (TCA, 400).

20. Circuit (100) according any one of the preceding claims, especially according to claim 1 or claim 2, wherein the circuit is configured such that the input signal is a signal (806) having a constant value or a value which does not change more than 10 percent from a maximum value within a time window (P2 to P6),
wherein the time window (P2 to P6) has a length of at least 1 second or of at least 10 seconds or of at least 30 seconds, and
wherein the circuit is configured such that changes of the output signal (826) based on variations of an impedance (Z) of a load at an output of the signal source may be predicted and/or detected.

21. Circuit (100) according to claim 20, wherein the circuit (100) is configured such that a first characteristic relates to a first signal value of the output signal (826) at a first time and a second characteristic relates to a second signal value of the output signal (826) at a second time which is after the first time,
wherein the circuit (100) is configured such that the first signal value and the second signal value are from the same raising or falling signal part of the electrical output signal,
and wherein the prediction unit (160) is configured to predict the change of the output signal (826) based on the first signal value and on the second signal value, preferably based on the difference of the second signal value and of the first signal value.

22. Medical device, especially brain stimulation device (D), comprising a circuit (100) according to one of the preceding claims, and
preferably at least one electrode (E1, E2), and
preferably a supporting structure for arranging the at least one electrode (E1, E2) on the head of a person, especially on the head of a person which is trained non-therapeutically by the brain stimulation device (D) or on the head of a patient which is treated therapeutically by the brain stimulation device (D).

23. Method, preferably using a circuit (100) according to one of the claims 1 to 21 or a brain stimulation device (D) according to claim 22, comprising:
providing a voltage converter (110, 300) which generates a supply voltage (+HV, −HV) dependent on a control signal (302, PWM),
providing a signal source (TCA, 400) which is powered by the supply voltage (+HV, −HV), wherein the signal source (TCA, 400) generates an output signal (I_PAT) dependent on an input signal (DAC_OUT1, DAC_OUT1; REQ_CURRENT, CURRENT_FEEDBACK),
predicting a change of a characteristic of the output signal (I_PAT), and
adjusting the control signal (302, PWM) dependent on the predicted change.

24. A non-transitory computer readable medium (M), having stored therein instructions that are executable to cause a control unit (P) to perform at least a part of or the method according to claim 23, and/or.
a computer program product comprising machine readable instruction which when executed on a control unit (P) cause the control unit (P) to perform at least a part of or the method according to claim 23, and/or
a system (100) comprising:
one control unit (P) or more than one control unit (P); and
a non-transitory computer-readable medium (M), configured to store computer-readable instructions that, when executed by the one or more control unit (P), cause the system (100) to perform at least a part of or the method of claim 23.

25. Circuit (100) for a medical device or for another electronic device, comprising:
a voltage converter (110, 300) which is configured to provide at least one supply potential (HV) depending on a control signal (302, PWM) provided to the voltage converter (110, 300),
a control unit (P) which is configured to provide the control signal (302, PWM) for the voltage converter (110, 300),
a signal source (TCA, 400) which is powered by the at least one supply potential (+HV) and which is configured to provide an output signal at an output of the signal source (TCA, 400), wherein the signal source (TCA, 400) is configured to provide the output signal dependent on an input signal (120) at an input of the signal source (TCA, 400),
wherein the control unit (P) comprises:
a prediction unit (160) which is configured to predict a change of a characteristic of the output signal based on at least one of a) at least one value of the input signal and b) at least one detected value of the output signal, and
an adjusting unit (160) which is configured to adjust the control signal (302, PWM) based on the predicted change in the characteristic of the output signal.
